(19) United States
(12) Patent Application Publication
(10) Pub. No.: US 2018/0309069 A1
(43) Pub. Date: Oct. 25, 2018

(54) Luminescent Device

(71) Applicant: AAC Technologies Pte, Ltd., Singapore city (SG)

(72) Inventor: Zaifeng Xie, Shenzhen (CN)

(21) Appl. No.: 15/955,850

(22) Filed: Apr. 18, 2018

(30) Foreign Application Priority Data
Apr. 21, 2017 (CN) 201710264980.X

(51) Int. Cl. H01L 51/00; H01L 51/50; C07F 15/00; C09K 11/06

(52) U.S. Cl. CPC H01L 51/0084; H01L 51/5028; C07F 15/006; C09K 11/06; C09K 2211/185; H01L 51/5056; H01L 51/5072; C09K 2211/1029; C09K 2211/1044; H01L 51/5016

(57) ABSTRACT

The disclosure relates to organic luminescence technology, in particular to a luminescent device having a first electrode, a second electrode and at least an organic luminescent layer arranged between the first electrode and the second electrode. The organic luminescent layer contains host material, metal-assisted delayed fluorescence sensitizer and fluorescence quenching agent; the metal-assisted delayed fluorescence sensitizer is an organic material which transfers a triplet exciton and a singlet exciton produced by electroluminescence to the fluorescence quenching agent; the fluorescence quenching agent is a fluorescent luminescent material which transfers the energy of all the triplet exciton to the singlet exciton and uses the singlet exciton for luminescence. The luminescent device in the invention has a very high energy utilization rate through the management of exciton in the organic luminescent layer, and significantly improves the luminescent efficiency and service life of the luminescent device.

### FIELD OF THE PRESENT DISCLOSURE

The invention relates to the field of organic luminescence technology, in particular to a luminescent device.

### DESCRIPTION OF RELATED ART

The luminescence mechanism of organic light-emitting diode (OLED) mainly comprises fluorescence and phosphorescence, and the former is mainly a process from singlet excited state to singlet state by using S1→S0, and the latter is mainly a process from triplet excited state to singlet state by using T1→S0. For fluorescent OLED, both holes and electron carriers are injected into the anode and cathode at the same time when the current is driven, and the carriers forms a singlet exciton S1 and three triplet excitons T1 in the host material of the luminescent layer, and then the energy of the singlet exciton S1 of the host material is transferred to the host material's singlet S. Finally, it will be luminescent in the guest material S1→S0. The energy efficiency of this process is relatively low, because, ideally, 25% of the singlet exciton (S1, host material) produced by electroluminescence is used for luminescence in guest material. However, the remaining 75% triplet exciton (T1, host material) is wasted due to spin forbidden resistance. For phosphorescent OLED material, when the current is driven, the holes and electron carriers injected at the anode and cathode at the same time form singlet and triplet exciton on the host material of EML in composite manner. However, due to the heavy metal effect in phosphorescent OLED material, the intersystem crossing from singlet to triplet can be enhanced, and 100% T1 exciton can be obtained theoretically, in order to achieve higher luminescence efficiency. The phosphorescence OLED can improve the performance of red light and green light, compared with fluorescent OLED. However, the lifetime of phosphorescent OLED (or referred to as PHOLED) and the performance attenuation at high current density are very serious, which seriously limits the further commercial application of PHOLED.

In order to further improve the efficiency and performance of OLED, especially the performance of devices with high current density, another kind of luminescence mechanism should be proposed.

### BRIEF DESCRIPTION OF THE DRAWINGS

Many aspects of the exemplary embodiments can be better understood with reference to the following drawings. The components in the drawing are not necessarily drawn to scale, the emphasis instead being placed upon clearly illustrating the principles of the present disclosure.

FIG. 1 is a schematic diagram of a luminescent device in an exemplary embodiment of the present disclosure;

FIG. 2 is a schematic diagram of the energy transfer path of the luminescent device for the invention;

FIG. 3 shows the molecular simulation of fluorescence quenching agent 4CzIPN.

FIG. 4 shows the absorption and photoluminescence spectra of metal-assisted delayed fluorescence sensitizer PdN3N.

10—Luminescent device;
11—First electrode;
12—Hole transport layer;
13—Organic luminescent layer;
14—Electron transport layer;
15—Second electrode.

### DETAILED DESCRIPTION OF THE EXEMPLARY EMBODIMENTS

The present disclosure will hereinafter be described in detail with reference to several exemplary embodiments. To make the technical problems to be solved, technical solutions and beneficial effects of the present disclosure more apparent, the present disclosure is described in further detail together with the figure and the embodiments. It should be understood the specific embodiments described hereby is only to explain the disclosure, not intended to limit the disclosure.

The present disclosure is further elaborated in combination with exemplary embodiments. It should be understood that these embodiments are used only to illustrate the invention and not to limit the scope in the invention.

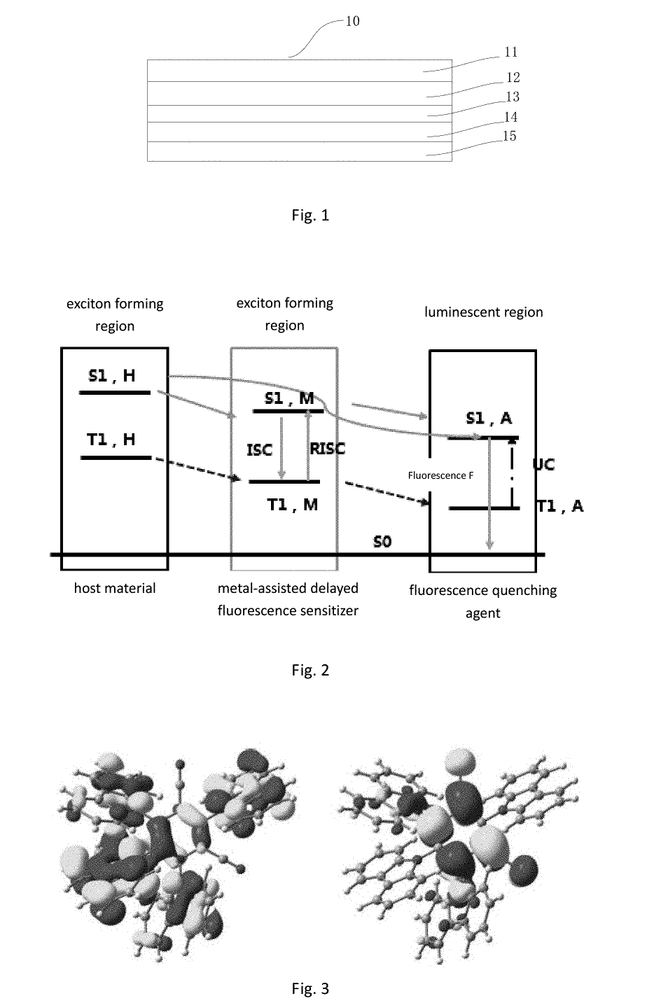

The invention provides a luminescent device, the structure of which is illustrated in FIG. 1, comprising a first electrode 11, a second electrode 15 and at least an organic luminescent layer 13 arranged between the first electrode 11 and the second electrode 15.

In the invention, the organic luminescent layer simultaneously contains a host material, a metal-assisted delayed fluorescence sensitizer and a fluorescence quenching agent.

The metal-assisted delayed fluorescence sensitizer is an organic material which transfers the triplet exciton and the singlet exciton produced by electroluminescence to the fluorescence quenching agent.

The fluorescence quenching agent is a fluorescent luminescent material which transfers the energy of all the triplet exciton to the singlet exciton and uses the singlet exciton for luminescence.

The organic luminescent layer in the invention simultaneously comprises a host material, a metal-assisted delayed fluorescence sensitizer and a fluorescence quenching agent. In the invention, the host material plays the role of forming a triplet exciton (T1) and a singlet exciton (S1), and the metal-assisted delayed fluorescence sensitizer acts as the transition for an exciton management or exciton transition, and transfers the triplet exciton and singlet exciton produced by electroluminescence to the fluorescence quenching agent, and the fluorescence quenching agent is used for fluorescence luminescence.

Generally speaking, in the host material: fluorescent emitter system, the host material is a place where the hole and electron are combined to form S1 and T1 exciton under the action of electric field. On the other hand, there are a few opportunities to form exciton forming regions in fluorescent emitter. T1 exciton formed in fluorescent emitter cannot be used for luminescence by itselves, which is limited by the different spin electron states between fluorescence S1 exciton and T1 exciton, resulting in low luminescence efficiency in the existing techniques.

The energy transfer between host material and fluorescent emitter is mainly dependent on FET energy transfer, and the efficiency of this energy transfer mainly depends on the overlap between the emission spectrum of host material and the absorption spectrum of guest material. The process of Forster Energy transfer (FET) is S1 (host)+S0 (guest)→S0(host)+S1(guest), i.e.: in the host-guest doped fluorescence system, the host material transfers the energy to the guest material by exchanging the energy of the singlet exciton, which is a near-field action, and it is required that the host material is very close to the guest material molecule, that is to say, the doping ratio of the host material should be very high, reaching at least 80% or even more than 90%. Therefore, in the prior art, most of the energy in the exciton composite region of the host material under the action of electric field cannot be utilized.

However, in the present disclosure, an energy sensitizer—a metal-assisted delayed fluorescence sensitizer (also known as an energy transporter, or an energy transition), is introduced. The metal-assisted delayed fluorescence sensitizer can utilize T1 exciton and S1 exciton, and the advantages of adding the sensitizer are as follows: on the one hand, S1 of the host material can be transferred to S1 of the sensitizer and then to S1 of the fluorescence quenching agent for luminescence; on the other hand, T1 of the original host material cannot be used by the luminescent material T1. However, the invention emits light via the energy conduction path of T1 (host)→T1 (sensitizer)→S1 (sensitizer)→S1 (fluorescence quenching agent), or emits light via T1 (host)→T1 (sensitizer)—via Dexter energy transfer-→T1 (fluorescence quenching agent)—via energy up-conversion UC-S1 (fluorescence quenching agent). Among them, the process of Dexter energy transfer and FET are two mutually competing processes free of radiation energy transfer.

Therefore, the invention uses the metal-assisted delayed fluorescence sensitizer as the transition medium of the triplet exciton, thus fully utilizing the energy in the triplet exciton generated by electroluminescence, and improving the luminescence efficiency of the luminescent device.

At the same time, the fluorescence quenching agent used in the invention not only directly receives the singlet exciton (S1), but also receives the triplet exciton (T1), and the exciton is managed by its own TTA-UC energy up-conversion mechanism, and all T1 is converted to S1 for fluorescence emission.

As an improvement of the luminescent device in the invention, in addition to the host material, the metal-assisted delayed fluorescence sensitizer also forms a triplet exciton and a singlet exciton when being excited. The metal-assisted delayed fluorescence sensitizer is used to manage exciton simultaneously using ISC and RISC, and finally all the energy is transferred to the singlet exciton and triplet exciton of fluorescence quenching agents through a variety of channels.

As an improvement of the luminescent device in the invention, when the fluorescence quenching agent is excited, the fluorescence quenching agent itself is excited and forms a triplet exciton and a singlet exciton, and the fluorescence quenching agent in the invention can use its own TTA-UC energy up-conversion to manage exciton and convert all triplet exciton into singlet exciton. Thus, the energy of exciton produced by fluorescence quenching agent is fully utilized, and the luminescence efficiency of the device is further improved.

The energy transfer path of the luminescent device in the invention is further explained below, as shown in FIG. 2, when the current drives the OLED, the hole is injected from the anode and the electron is injected from the cathode. The hole carrier and the electron carrier are recombined on the host material or on the metal-assisted delayed fluorescence sensitizer to form a hole electron pair (exciton). The energy of the exciton is transferred to the fluorescence quenching agent for fluorescence. The energy transfer path is as follows:

Route 1:

S1,H→S1,M: the FET energy transfer process from the singlet exciton (S1) of the host material (H) to the singlet exciton (S1) of the metal-assisted delayed-fluorescence sensitizer (M);

S1, M→S1, A: the FET process from the singlet exciton (S1) of the metal-assisted delayed fluorescence sensitizer (M) to the singlet exciton (S1) of the fluorescence quenching agent (A);

S1,M→T1,M: the intermolecular transition of metal-assisted delayed fluorescence sensitizer (M) was carried out by ISC mechanism.

Route 2:

S1, H→S1, A: the singlet exciton (S1) of the host material (H) is transferred directly to the singlet exciton (S1) of the fluorescence quenching agent (A) via FET.

Route 3:

T1,H→T1,M: the triplet exciton (T1) of the host material (H) is transferred to the triplet exciton (T1) of the metal-assisted delayed fluorescence sensitizer (M) via DET.

T1,M→S1,A: the triplet exciton (T1) energy of metal-assisted delayed fluorescence sensitizer (M) can be transferred to the singlet exciton (S1) of fluorescence quenching agent (A) via the FET mechanism.

T1, M→S1,M: the triplet exciton (T1) of metal-assisted delayed fluorescence sensitizer (M) is transitioned back to the singlet exciton (S1) of the metal-assisted delayed fluorescence sensitizer (M) via the RISC mechanism.

Route 4:

T1,A→S1,A: the triplet exciton (T1) of fluorescence quenching agent (A) is transferred to the singlet exciton (S1) of fluorescence quenching agent (A) via either the TTA-UC up-conversion mechanism or the TADF-UC mechanism.

Among them, in FIG. 2, the fluorescence F refers to the fluorescence of final exciton on the quenching agent; the region of exciton formation refers to the recombination region of holes and electrons in the electroluminescence process; the luminescent region refers to the region in which the exciton of the OLED deactivates and returns to the base state and releases photons.

Intersystem crossing (ISC) refers to the transition process of S1-T1.

Reversed Intersystem crossing (RISC) refers to T1-S1 process.

The type of forster energy transfer (FET): FET is the energy transfer process of T1-S1, S1-S1 between the donor and the acceptor.

Dexter energy transfer (DET), is the energy transfer process of T1-T1 between donor and acceptor molecules.

Energy up-conversion (UC) refers to the process of energy up-conversion from T1 to S1, including TTA-UC mechanism and TADF-UC mechanism.

The invention effectively ensures that all excitons in the electroluminescence process are transferred to the fluorescence quenching agent for luminescence through the plurality of exciton management modes. Thus, the luminescent utilization efficiency of the luminescent device can be raised to the extreme level.

As an improvement of the luminescent device in the invention, the material of the fluorescence quenching agent is selected from P type delayed fluorescence material or E type delayed fluorescence material.

P-type delayed fluorescence material refers to the material of TTA up-conversion, and E-type delayed fluorescence material refers to the material that uses TADF heat delay for fluorescence. Among them, P-type delayed fluorescence comes from a process where two triplets are quenched to form a singlet (TTA). E-type delayed fluorescence refers to that when the energy of the triplet excited state is close to that of the singlet excited state, the triplet excited state can be crossed to the singlet excited state by the thermal activation of the reverse system, which is also known as thermal activation delayed fluorescence (TADF).

The fluorescence quenching agent in the invention is a fluorescent material capable of utilizing a TTA-UC or TADF-UC up-conversion mechanism. P-type delayed fluorescence material can be used to transfer T1 to S1 by TTA-UC. E-type delayed fluorescence, also known as thermal activated delayed fluorescence (TADF), can be used to transfer T1 to S1 by TADF-UC, with D-A, A-D-A, D-A-D or D-SP-A structural characteristics. Among them, D is an electron donor, A is an electron acceptor, SP is an organic fragment with spatial solid or barrier, such as tetrahedron carbon in fluorene. HOMO and LUMO were separated from each other in the molecular configuration, and ΔE(S1−T1)≤0.5 eV, the molecular simulation diagram of fluorescence quenching agent 4CzIPN is shown in FIG. 3. As shown in FIG. 3, HOMO and LUMO are separated (Homo on the left and LUMOL on the right).

As an improvement of the luminescent device in the invention, the mass percentage content of the host material in the organic luminescent layer is A, and the mass percentage content of the metal-assisted delayed fluorescence sensitizer in the organic luminescent layer is B, and the mass percentage content of fluorescence quenching agent in the organic luminescent layer is C, A, B, C meet: A/(A+B+C)>60%.

Further preferably, A, B, C meet: A/(A+B+C)≥70%.

According to the proportions of the host material accounting for all three kinds of materials in the invention, the host material in the present disclosure is used as an organic material to form a triplet exciton and a singlet exciton. The auxiliary delayed fluorescence sensitizer and the fluorescence quenching agent are used as only a small amount of doped guest materials in the organic layer.

If the proportion of the host material in all three materials in the present disclosure is less than 60%, the mass percentage content of the metal-assisted delayed fluorescence sensitizer increases, which belongs to the co-host or mixed host luminescent structure of the host material+fluorescent luminescence material, and the luminescent structure of co-host or mixed host is characterized by the use of two or more host materials as the host materials of fluorescent luminescence, and all the excitons produced by electroluminescence are converted into S1 type exciton by the host materials and eventually transferred by various energy transfer mechanisms to the S1 of the fluorescent materials for luminescence instead of T1, thus reducing luminescent efficiency. Because in the host material+guest material mixed system of the existing technology, the energy transfer between host material and guest material is mainly carried out by FET. Generally, there is only a transfer of S1 (host)→S1 (guest) allowed, and T1 (host)→T1 (guest) is the process of DET energy transfer, and its probability of occurrence is very small. As a result, the energy of the host material T1 is wasted instead of being used.

In the invention, the host material with high mass percentage is used for formed T1 and S1; the metal-assisted delayed fluorescence sensitizer with low mass percentage was used as the energy conduction agent; the host material T1 can be directly transferred to fluorescence quenching agent T1 to form fluorescence quenching agent S1 for luminescence; alternatively, the host material T1 is transferred to the metal-assisted delayed fluorescence sensitizer T1, and to the metal-assisted delayed fluorescence sensitizer S1 via RISC, and then the fluorescence quenching agent S1 is transferred via FET for luminescence. Thus, the T1 formed by the host material is fully utilized.

As an improvement of the luminescent device in the invention, the mass percentage content of the host material in the organic luminescent layer is A, and the mass percentage content of the metal-assisted delayed fluorescence sensitizer in the organic luminescent layer is B, and the mass percentage contents of fluorescence quenching agents in the organic luminescent layer is C, A, B, C meet: B/(A+B+C)<20%.

Further preferably, A, B, C meet: B/(A+B+C)≤15%;

Further preferably, A, B, C meet: B/(A+B+C)≤10%. According to the proportion of metal assisted delayed fluorescence sensitizer accounting for all three kinds of materials, the auxiliary delayed fluorescence sensitizer is only used as a small amount of doped guest material in organic layer. In addition, because the metal-assisted delayed fluorescence sensitizer material itself is a geometric plane structure, the high doping concentration of metal-assisted delayed fluorescence sensitizer will have adverse optical effect. However, the invention reduces the use of metal-assisted delayed fluorescence sensitizer in the organic luminescent layer, thus making the color more pure and gorgeous. This is due to the fact that, if the content of metal-assisted delayed fluorescence sensitizer is high, i.e., as the host material, the metal-assisted delayed fluorescence sensitizer material is a transition metal complex containing platinum, of which the intermediate platinum is tetrahedral and has a pair of solitary electrons, and when the concentration of platinum complex is relatively large (i.e., as the host material), the platinum with two planar structures will chemically react to form dimer, and the resulting spectral redshift will not only affect the purity of the color, but also affect the energy transfer efficiency between the host and the guest. However, the invention adopts a small amount of doping of metal-assisted delayed fluorescence sensitizer, thus completely avoiding the negative optical effect of high doping concentration metal-assisted delayed fluorescence sensitizer.

As an improvement of the luminescent device in the invention, the mass percentage content of the host material in the organic luminescent layer is A, and the mass percentage content of the metal-assisted delayed fluorescence sensitizer in the organic luminescent layer is B, and the mass percentage contents of fluorescence quenching agents in the organic luminescent layer is C,

A, B, C meet: C/(A+B+C)<20%.

In the prior art, HOST+TADF is used as an organic luminescent layer, whose luminescence efficiency depends on the number of TADF molecules. Under high current driving conditions, the number of exciton produced increases rapidly (compared with the low current density), the high concentration of TADF materials leads to the quenching of many singlet excitons, e.g.: singlet-singlet annihilation process (SSA), ROLL-OFF of the efficiency of TADF. The ROLL-OFF of the efficiency of blue TADF materials at high current density is also very serious. In the invention, the TADF doping concentration is low, thus reducing the required exciton concentration under the same luminescent efficiency, and slowing down ROLL-OFF of the efficiency under the high current.

As an improvement of the luminescent device in the invention, ΔE(S1−T1) of the metal-assisted delayed fluorescence material is <0.3 Ev, and the metal-assisted delayed fluorescence materials can simultaneously utilize the triplet exciton and the singlet exciton for luminescence at room or high temperature.

As an improvement of the luminescent device in the invention, the metal-assisted delayed fluorescence sensitizer is selected from a compound shown in the following general formulas:

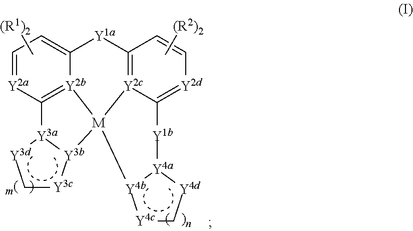

In the general formula I:

M denotes Ir, Rh, Ni, Cu, Ag;

R1 or R2 denotes hydrogen atoms, halogen atoms, hydroxyl groups, mercaptan groups, amino groups, substituted or unsubstituted alkyl, substituted or unsubstituted alkynes, substituted or unsubstituted naphthenic, substituted or unsubstituted cycloolefin, substituted or unsubstituted alkoxyl independently, respectively;

Y1a or Y1b denotes O, NR3, CR3R4, S, AsR3, BR3, PR3, P(O)R3, SiR3R4 independently, respectively, and R3 or R4 selected from hydrogen atoms, halogen atoms, hydroxyl groups, mercaptyl groups, amino groups, substituted or unsubstituted alkyl groups, substituted or unsubstituted alkynes, substituted or unsubstituted naphthenic alkyl, substituted or unsubstituted cycloalkenes, substituted or unsubstituted alkoxyl independently, respectively;

Y2a, Y2b, Y2c, Y2d denotes N and CR5 independently, respectively, and R5 is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloalkenes, substituted or unsubstituted alkoxyl;

Y3a, Y3b, Y3c, Y3d, Y4a, Y4b, Y4c, Y4d denotes N, O, S, NR6, CR7 independently, respectively; R6 or R7 is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloolefins, substituted or unsubstituted alkoxyl;

m is 1 or 2, n is 1 or 2;

[symbol] represents an unsaturated ring.

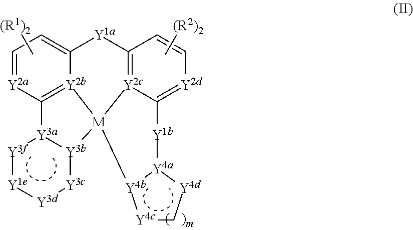

In the general formula II:

m denotes Pt, Pd, Au;

R¹ or R² denotes hydrogen atoms, halogen atoms, hydroxyl groups, mercaptan groups, amino groups, substituted or unsubstituted alkyl, substituted or unsubstituted alkynes, substituted or unsubstituted naphthenic, substituted or unsubstituted cycloolefin, substituted or unsubstituted alkoxyl independently, respectively;

Y^{1a} or Y^{1b} denotes O, NR³, CR³R⁴, S, AsR³, BR³, PR³, P(O)R³, SiR³R⁴ independently, respectively, and R³ or R⁴ is selected from hydrogen atoms, halogen atoms, hydroxyl groups, mercaptyl groups, amino groups, substituted or unsubstituted alkyl groups, substituted or unsubstituted alkynes, substituted or unsubstituted naphthenic alkyl, substituted or unsubstituted cycloalkenes, substituted or unsubstituted alkoxyl;

Y^{2a}, Y^{2b}, Y^{2c}, Y^{2d} denotes N and CR⁵ independently, respectively, and R⁵ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloalkenes, substituted or unsubstituted alkoxyl;

Y^{3a}, Y^{3b}, Y^{3c}, Y^{3d}, Y^{4a}, Y^{4b}, Y^{4c}, Y^{4d} denotes N, O, S, NR⁶, CR⁷ independently, respectively; R⁶ or R⁷ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloolefins, Substituted or unsubstituted alkoxyl;

m is 1 or 2;

[symbol] represents an unsaturated ring.

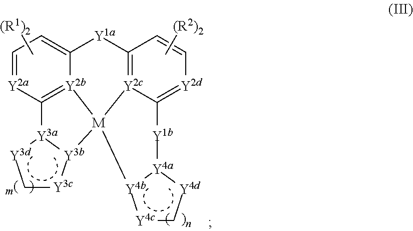

In the general formula III:

M is Pt, Pd, Au, Ag;

R¹ or R² denotes hydrogen atoms, halogen atoms, hydroxyl groups, mercaptan groups, amino groups, substituted or unsubstituted alkyl, substituted or unsubstituted alkynes, substituted or unsubstituted naphthenic, Substituted or unsubstituted cycloolefin, substituted or unsubstituted alkoxyl independently, respectively;

One of the Y^{1a} or Y^{1b} denotes B(R³)₂, and the other denotes O, NR³, CR³R⁴, S, AsR³, BR³, PR³, P(O)R³, SiR³R⁴, and R³ or R⁴ is selected from hydrogen atoms, halogen atoms, hydroxyl groups, mercaptyl groups, amino groups, substituted or unsubstituted alkyl groups, substituted or unsubstituted alkynes, substituted or unsubstituted naphthenic alkyl, substituted or unsubstituted cycloalkenes, substituted or unsubstituted alkoxyl;

Y^{2a}, Y^{2b}, Y^{2c}, Y^{2c} denotes N and CR⁵ independently, respectively, and R⁵ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloalkenes, substituted or unsubstituted alkoxyl;

Y^{3a}, Y^{3b}, Y^{3c}, Y^{3d}, Y^{4a}, Y^{4b}, Y^{4c}, Y^{4d} denotes N, O, S, NR⁶, CR⁷ independently, respectively; R⁶ or R⁷ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloolefins, substituted or unsubstituted alkoxyl;

m is 1 or 2, n is 1 or 2;

[symbol] represents an unsaturated ring;

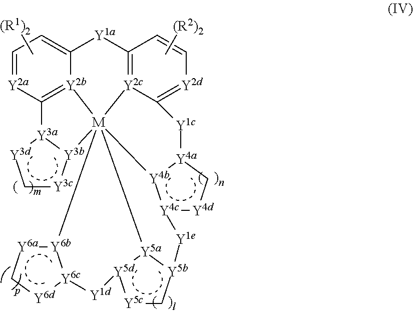

In the general formula IV:

M denotes Ir, Rh, Os, Co, Ru;

R¹ or R² denotes hydrogen atoms, halogen atoms, hydroxyl groups, mercaptan groups, amino groups, substituted or unsubstituted alkyl, substituted or unsubstituted alkynes, substituted or unsubstituted naphthenic, substituted or unsubstituted cycloolefin, substituted or unsubstituted alkoxyl independently, respectively;

Y^{1a}, Y^{1b}, Y^{1c}, Y^{1d} denotes O, NR³, CR³R⁴, S, AsR³, BR³, PR³, P(O)R³, SiR³R⁴ independently, respectively, and R³ or R⁴ is selected from hydrogen atoms, halogen atoms, hydroxyl groups, mercaptyl groups, amino groups, substituted or unsubstituted alkyl groups, substituted or unsubstituted alkynes, substituted or unsubstituted naphthenic alkyl, substituted or unsubstituted cycloalkenes, substituted or unsubstituted alkoxyl;

Y^{1e} denotes virtual atoms, O, NR³, CR³R⁴, S, AsR³, BR³, PR³, P(O)R³, SiR³R⁴, and R³ or R⁴ is selected from hydrogen atoms, halogen atoms, hydroxyl groups, mercaptyl groups, amino groups, substituted or unsubstituted alkyl groups, substituted or unsubstituted alkynes, substituted or unsubstituted naphthenic alkyl, substituted or unsubstituted cycloalkenes, substituted or unsubstituted alkoxyl; the virtual atom indicates that the group does not exist;

Y^{2a}, Y^{2b}, Y^{2c}, Y^{2d} denotes N, CR⁵ independently, respectively, and R⁵ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloalkenes, substituted or unsubstituted alkoxyl;

Y^{3a}, Y^{3b}, Y^{3c}, Y^{3d}, Y^{4a}, Y^{4b}, Y^{4c}, Y^{4d} denotes N, O, S, NR⁶, CR⁷ independently, respectively; R⁶ or R⁷ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloolefins, substituted or unsubstituted alkoxyl;

m is 1 or 2, n is 1 or 2, and l is 1 or 2;

[symbol] represents an unsaturated ring.

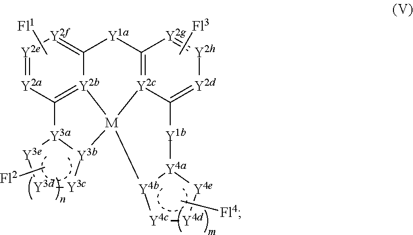

In the general formula V:

M is Pt, Pd, Au, Ir, Rh, Ni, Cu, Ag;

Y^{1a} or Y^{1b} denotes O, NR³, CR³R⁴, S, AsR³, BR3, BR³, P(O)R³, SiR³R⁴ independently, respectively, and R³ or R⁴ is selected from hydrogen atoms, halogen atoms, hydroxyl groups, mercaptyl groups, amino groups, substituted or unsubstituted alkyl groups, substituted or unsubstituted alkynes, substituted or unsubstituted naphthenic alkyl, substituted or unsubstituted cycloalkenes, substituted or unsubstituted alkoxyl;

Y^{2a}, Y^{2b}, Y^{2c}, Y^{2d} denotes N, CR⁵ independently, respectively, and R⁵ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloalkenes, substituted or unsubstituted alkoxyl;

Y^{3a}, Y^{3b}, Y^{3c}, Y^{3d}, Y^{4a}, Y^{4b}, Y^{4c}, Y^{4d} denotes N, O, S, NR⁶, CR⁷ independently, respectively; R⁶ or R⁷ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloolefins, substituted or unsubstituted alkoxyl;

m is 1 or 2, n is 1 or 2;

[symbol] represents an unsaturated ring;

FI¹, FI², FI³, FI⁴ denotes fluorescent illuminant independently, respectively, and FI¹, FI², FI³, FI⁴ exists independently or doesn‘t’ exist, and at least one of them exists.

If FI¹, FI², FI³, FI⁴ exist, at least one of the FI¹, the FI², the FI³ and the FI⁴ is associated with Y^{2a}, Y^{2d}, Y^{2e}, Y^{2f}, Y^{2g}, Y^{2h}, Y^{3c}, Y^{3d}, Y^{3e}, Y^{4c}, Y^{4d}, Y^{4e} by covalent bonds.

As an improvement of the luminescent device in the invention, FI¹, FI², FI³, FI⁴ denotes substituted or unsubstituted C_{1˜24} alkyl, substituted or unsubstituted C_{2˜24} alkyl, substituted or unsubstituted C_{2˜24} alkyl, substituted or unsubstituted C_{6˜72} aryl, substituted or unsubstituted C_{6˜72} aryl independently, respectively;

The substituents are selected from halogen, nitro, hydroxyl, cyanide, nitrile, isonitrile, amino, sulfhydryl, mercaptol, sulfonyl, sulfonyl, carboxyl, hydrazine, C_{6˜24} aryl, C_{6˜24} aryl group, C_{6˜24} hetero aryl group, C_{1˜12} alkyl group, C_{2˜12} enyl group.

As an improvement of the luminescent device in the invention, FI¹, FI², FI³, FI⁴ is selected from the substituents expressed in the following structures:

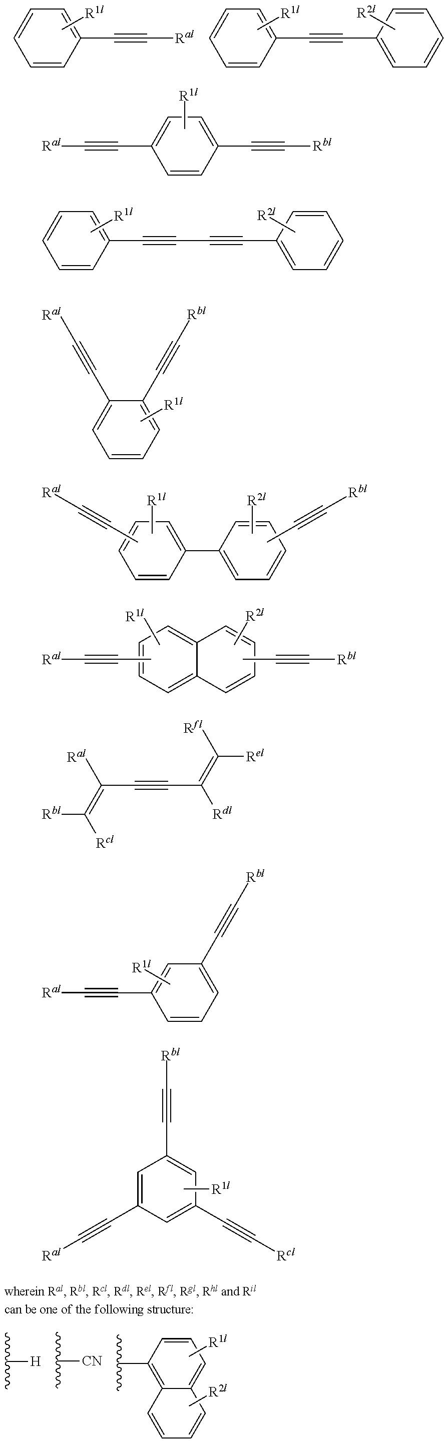

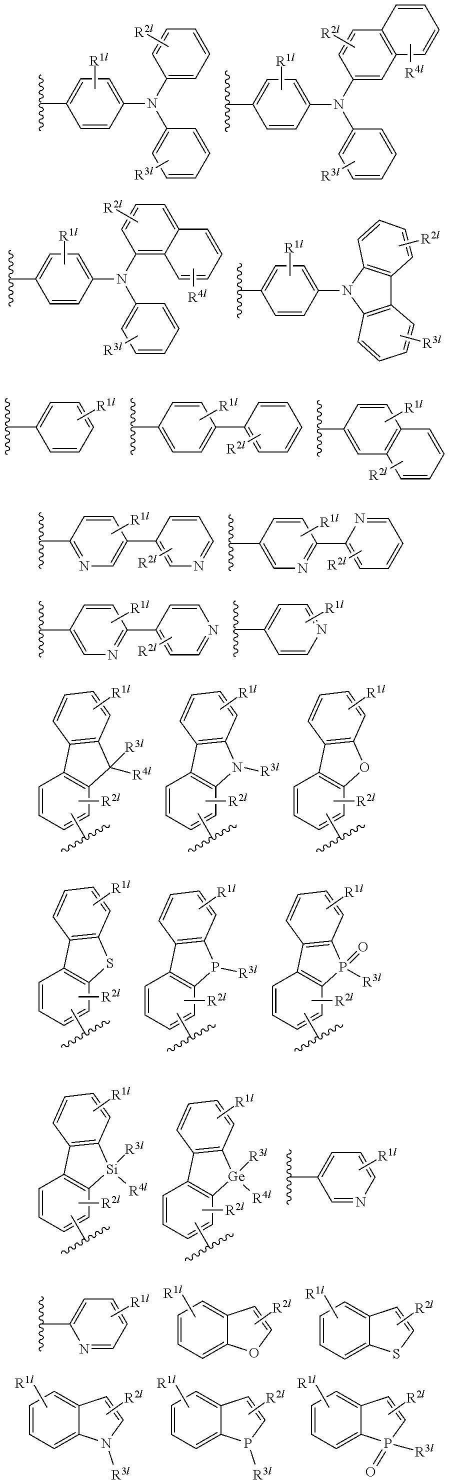

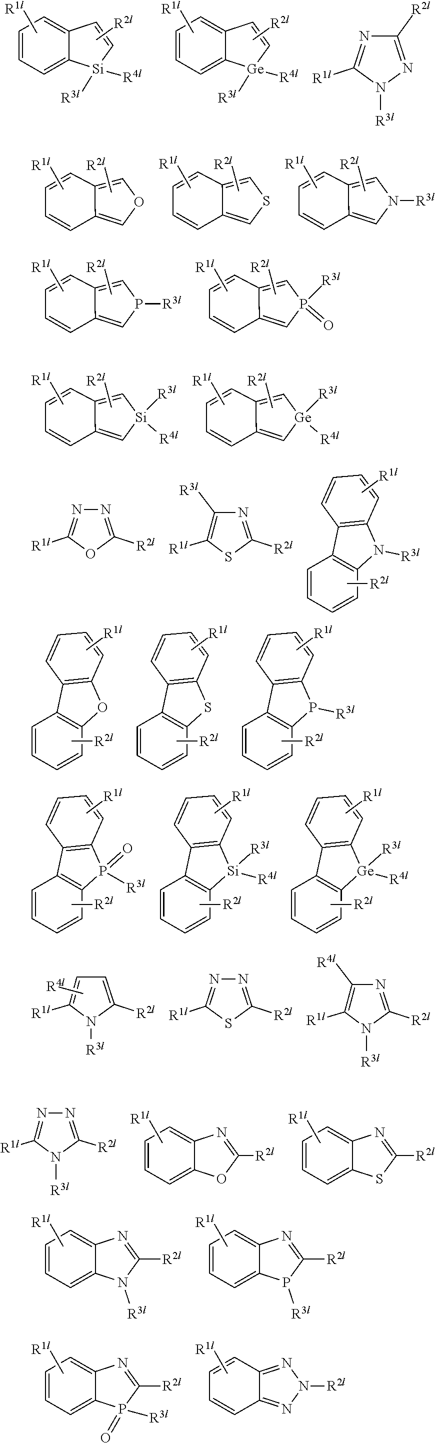

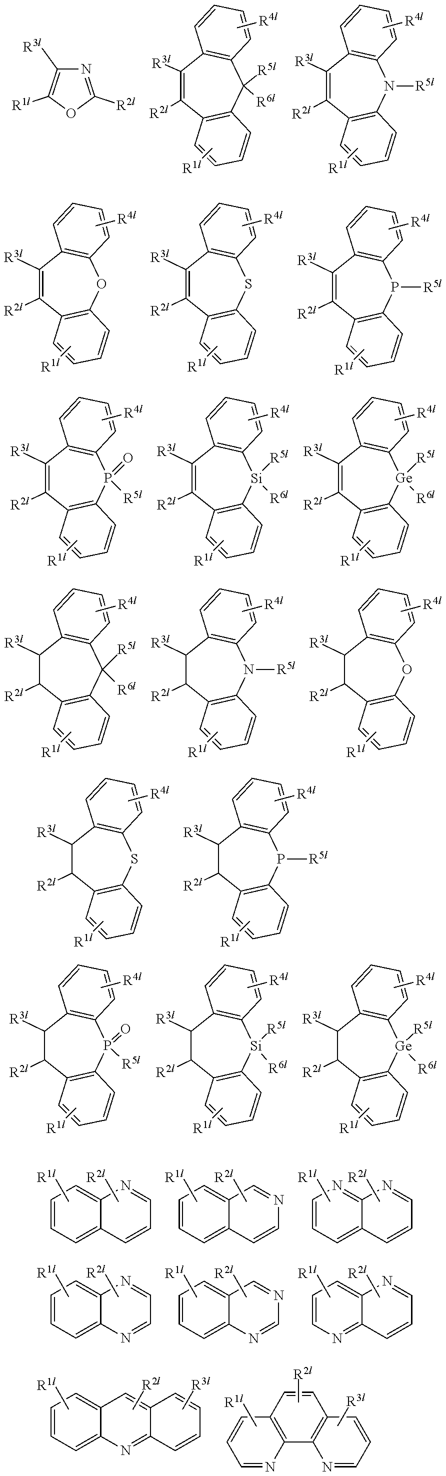

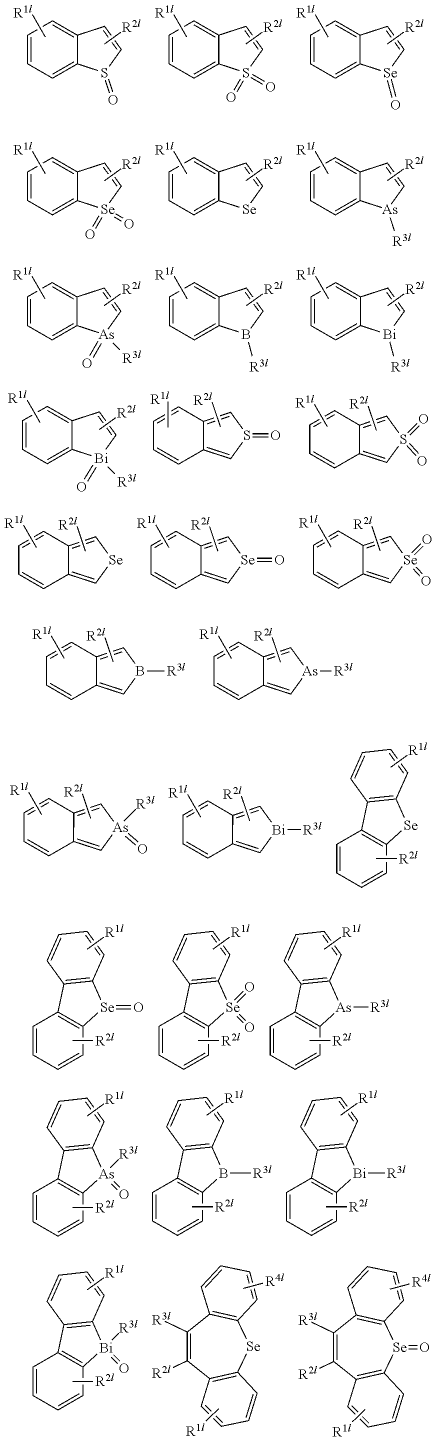

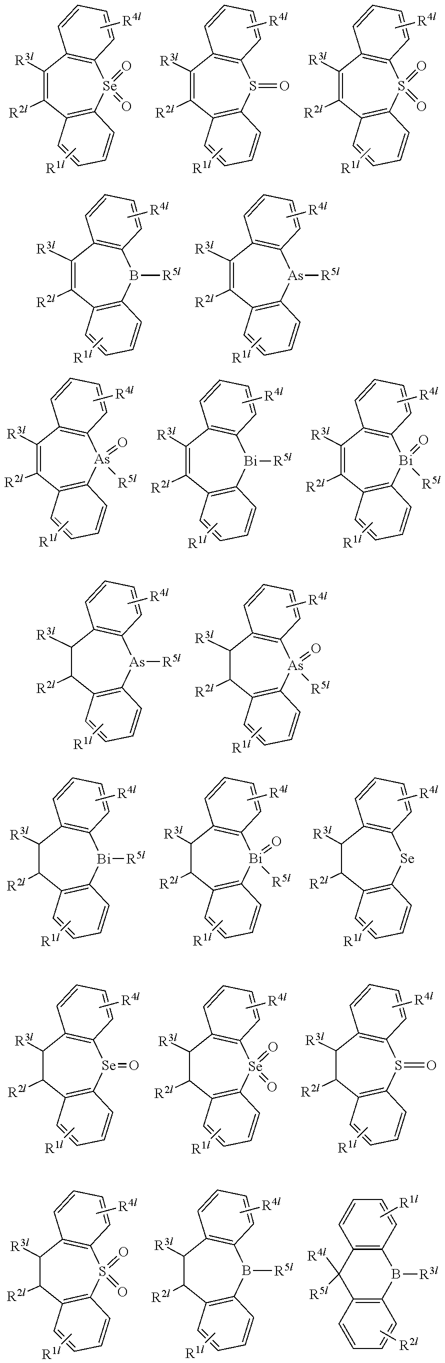

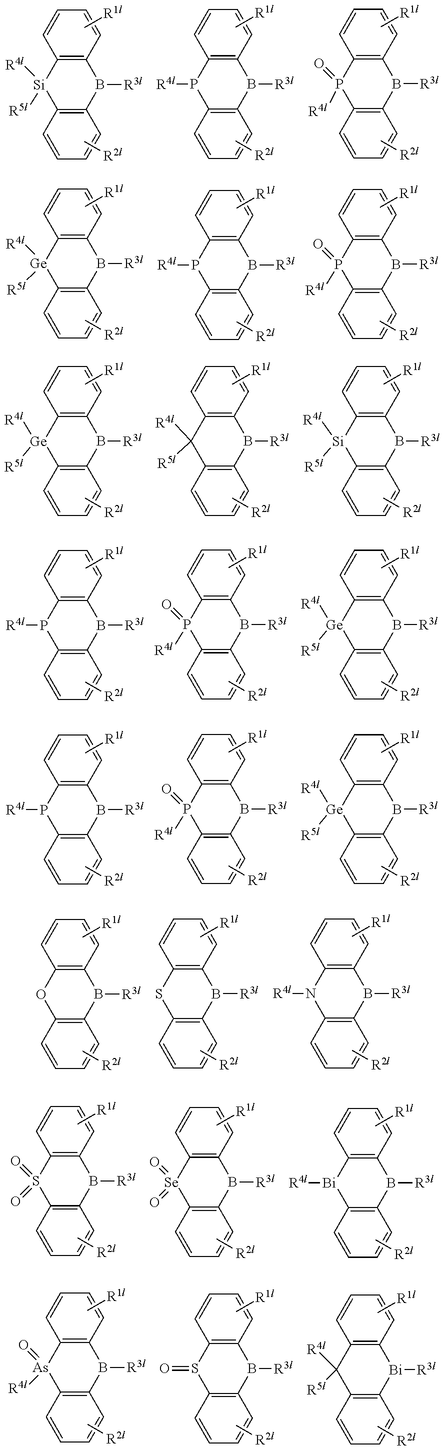

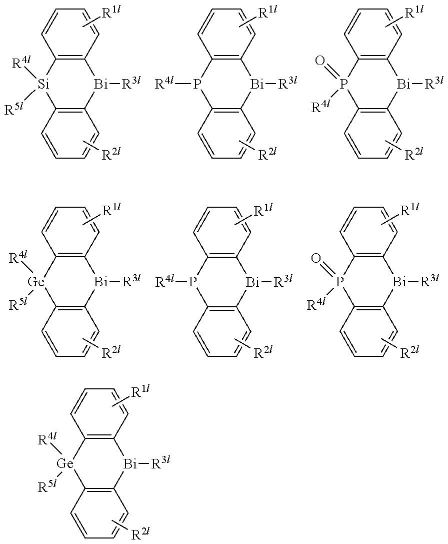

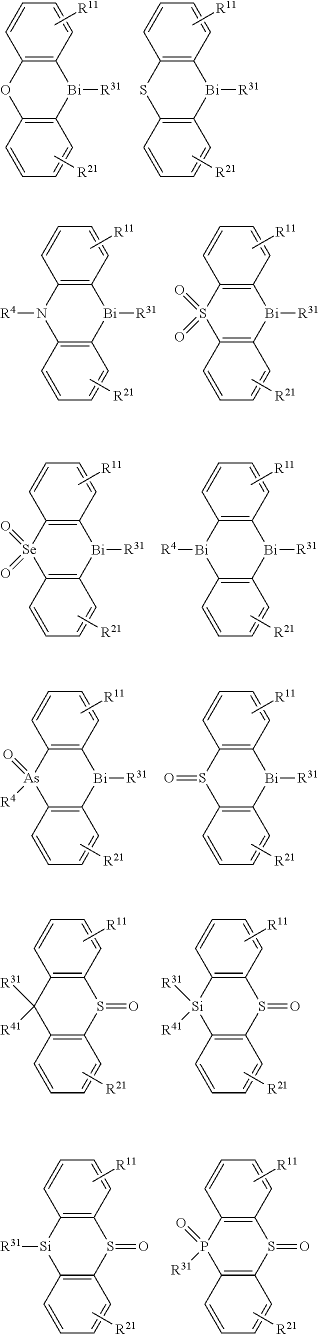

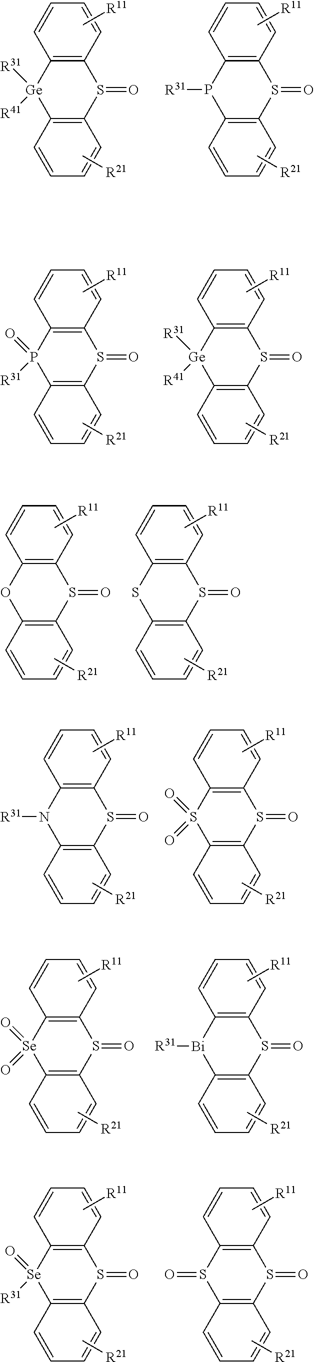

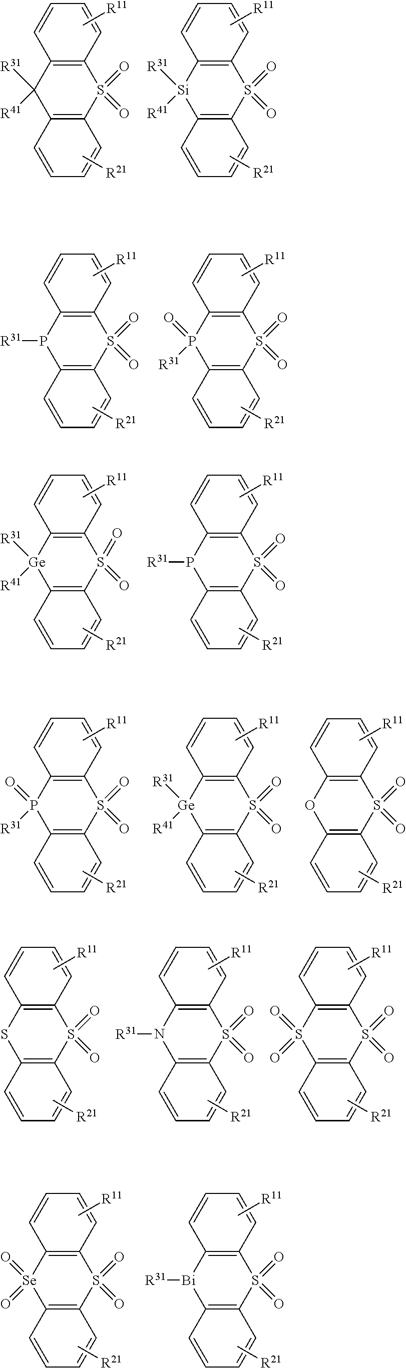

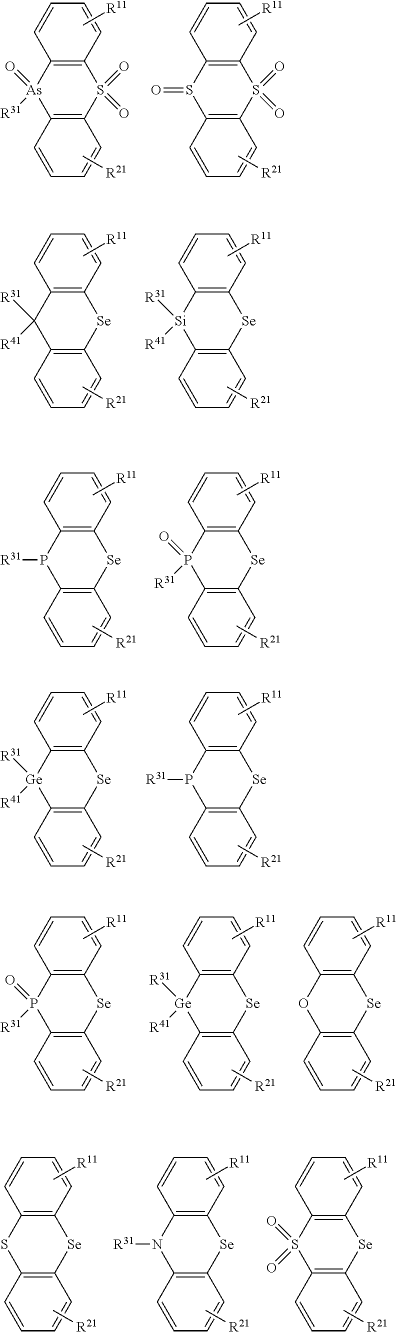

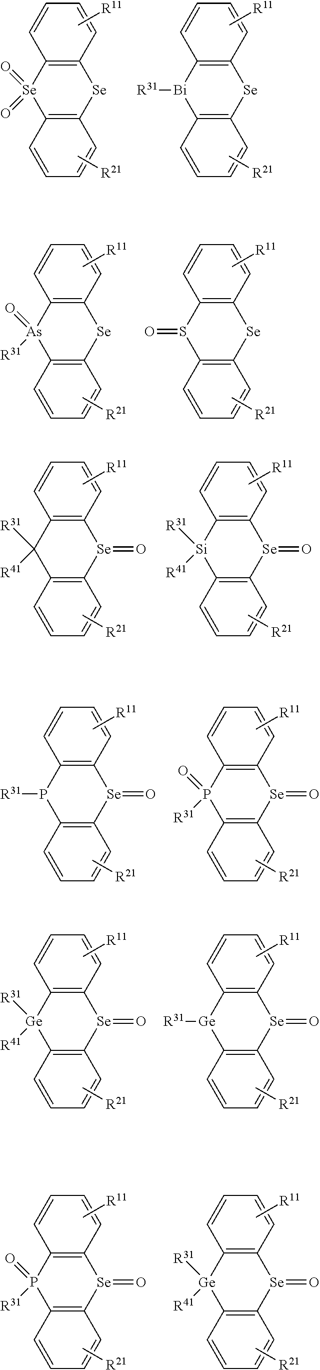

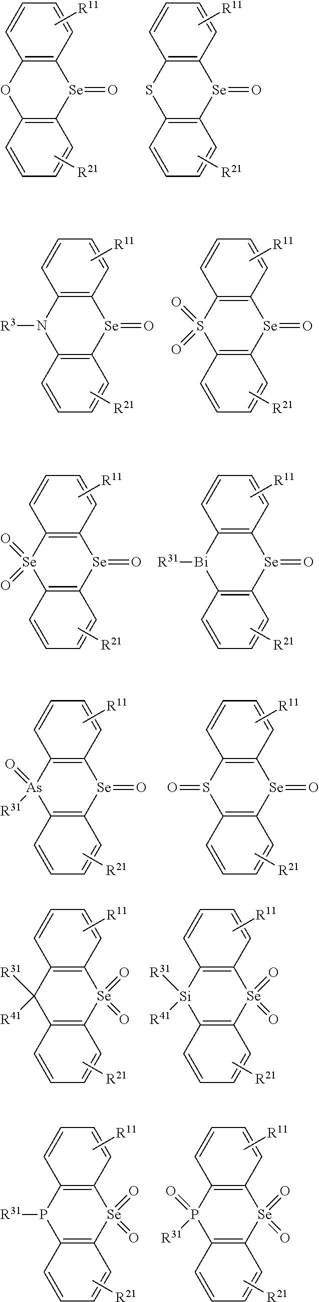

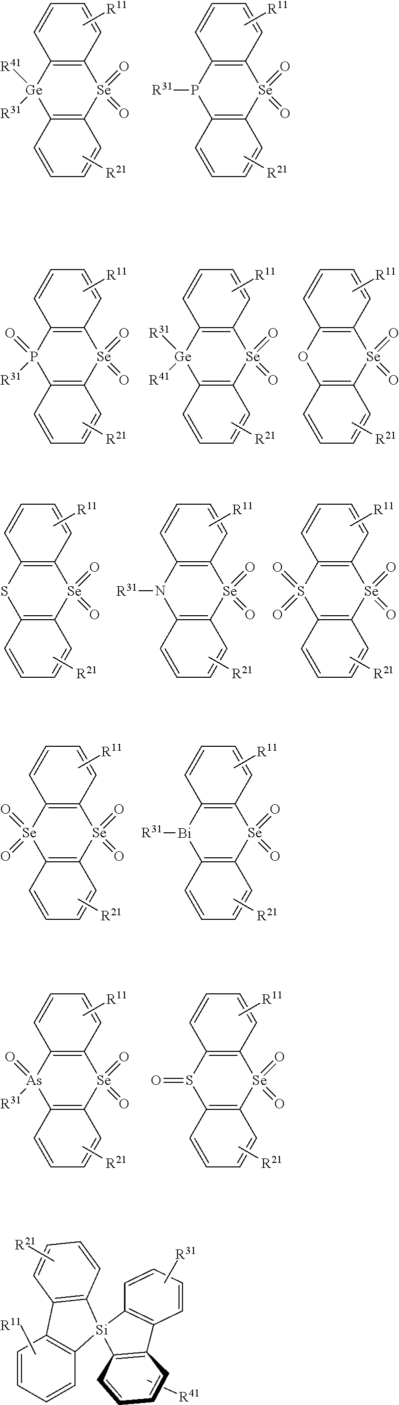

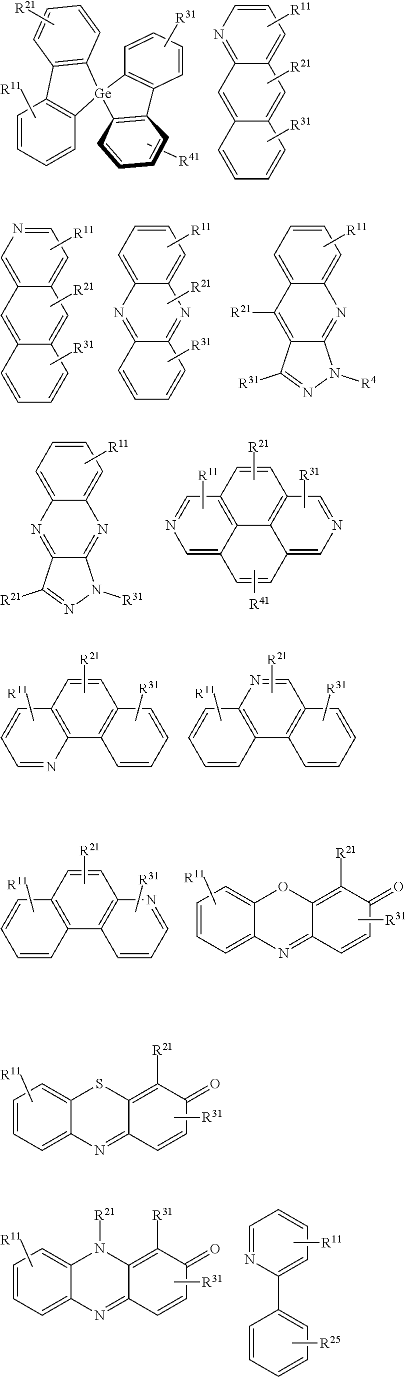

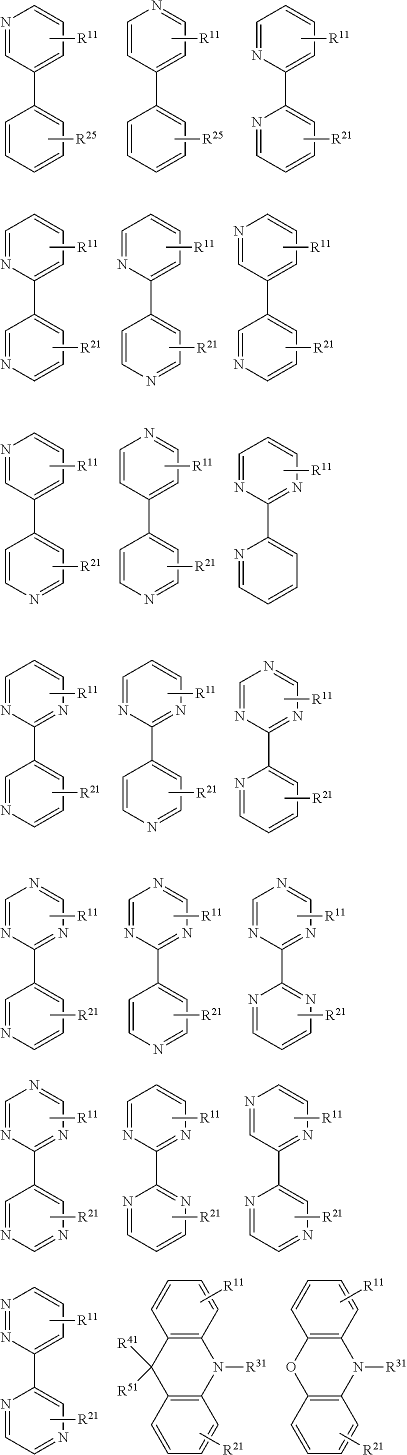

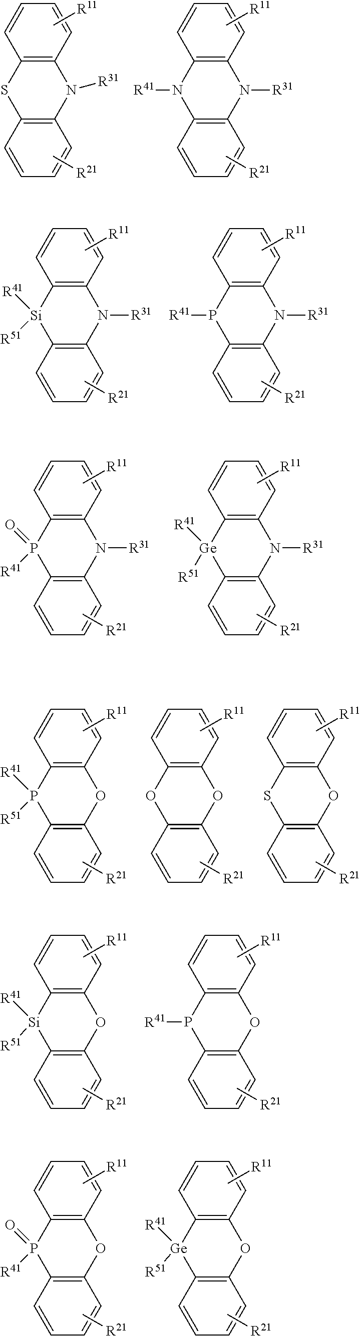

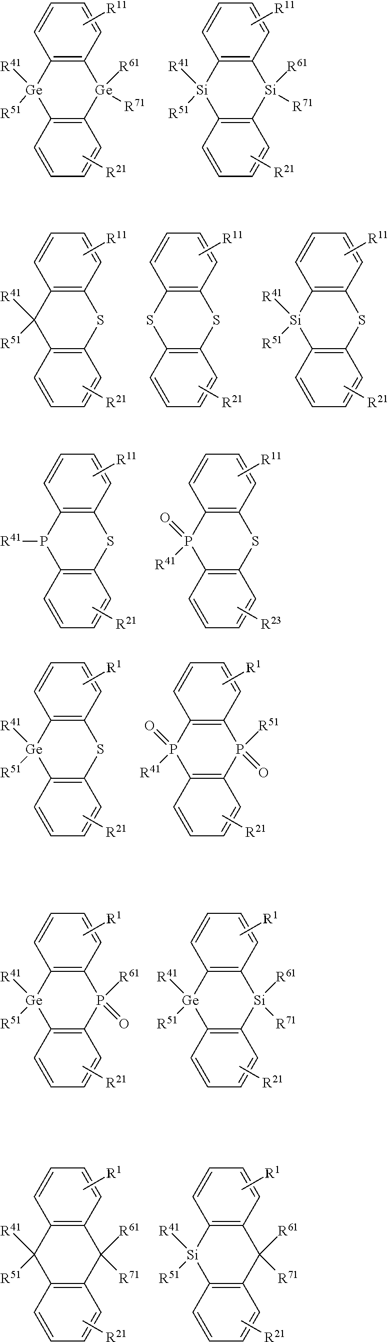

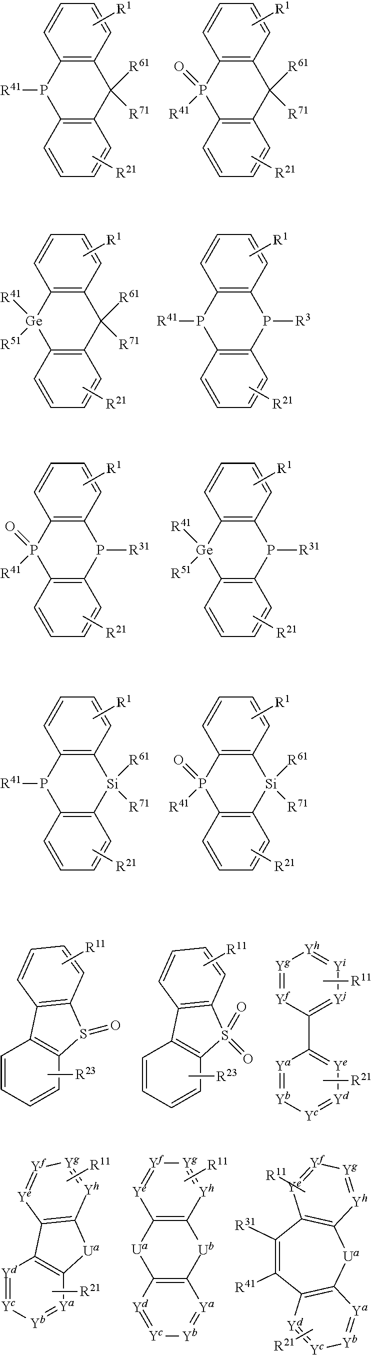

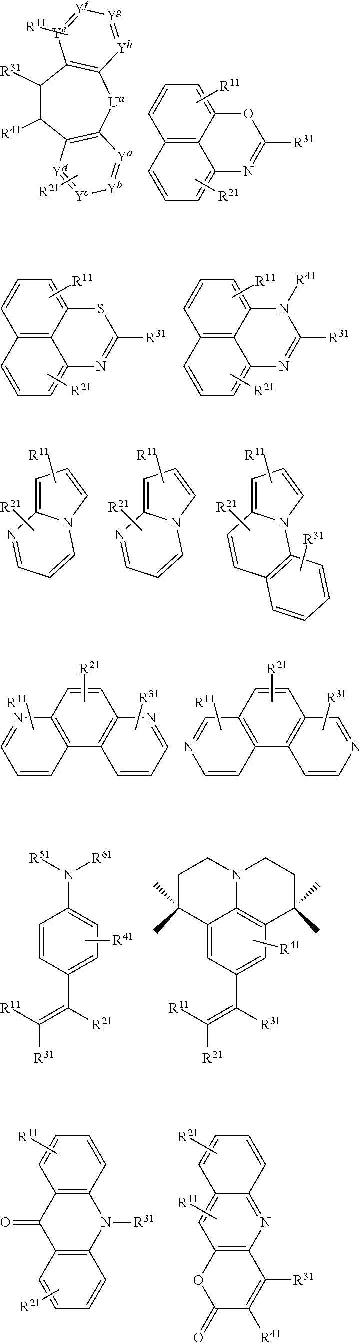

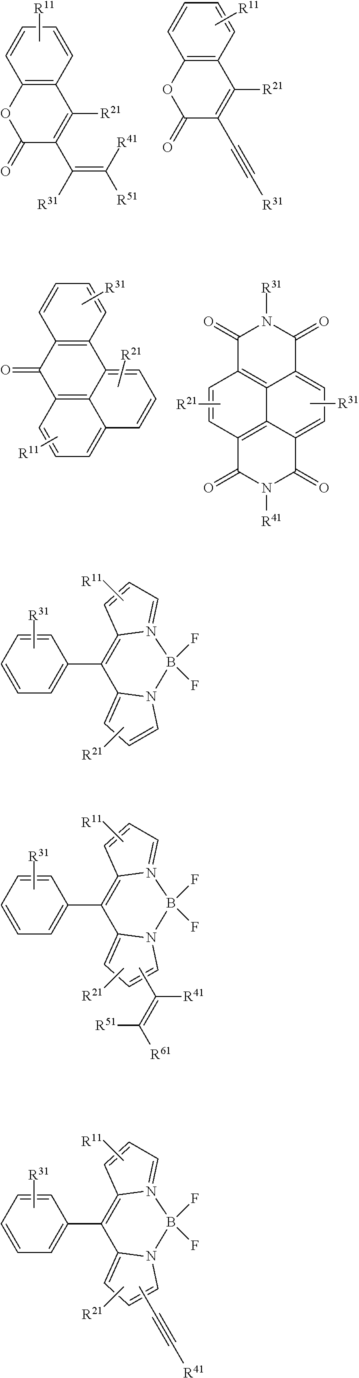

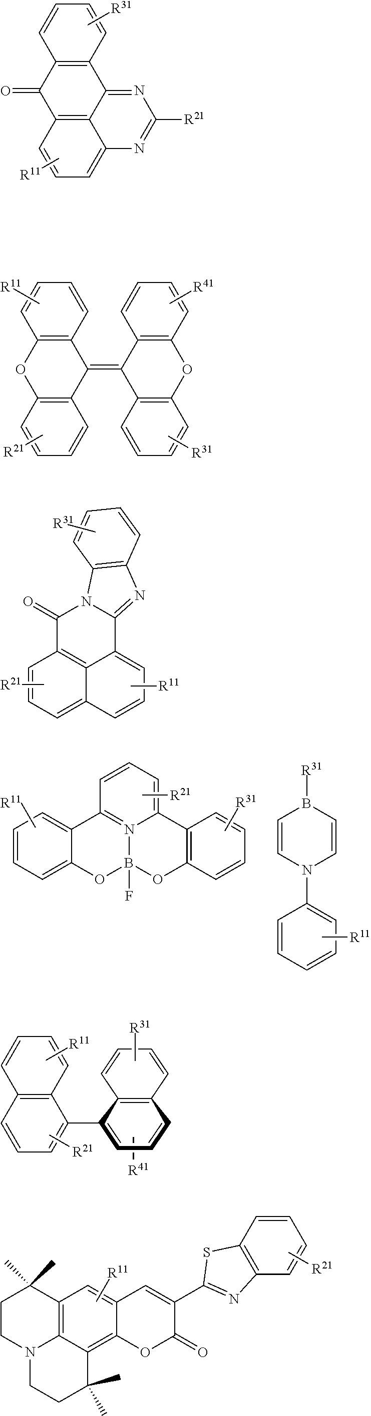

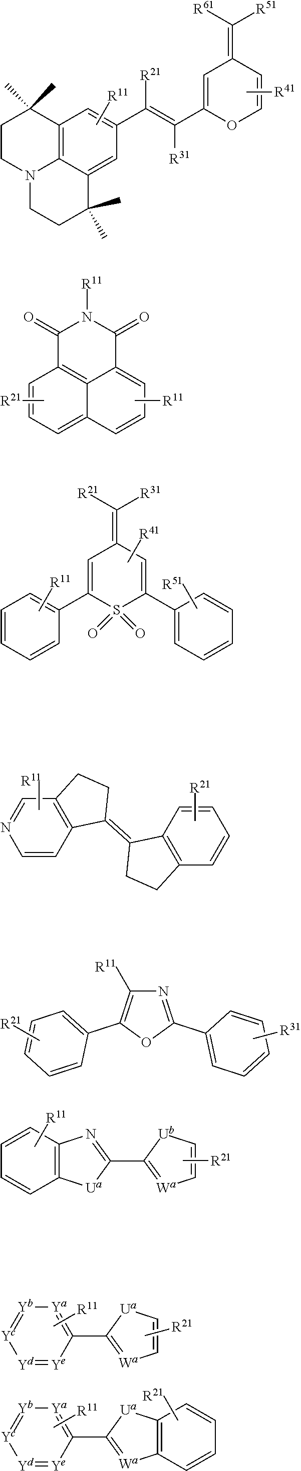

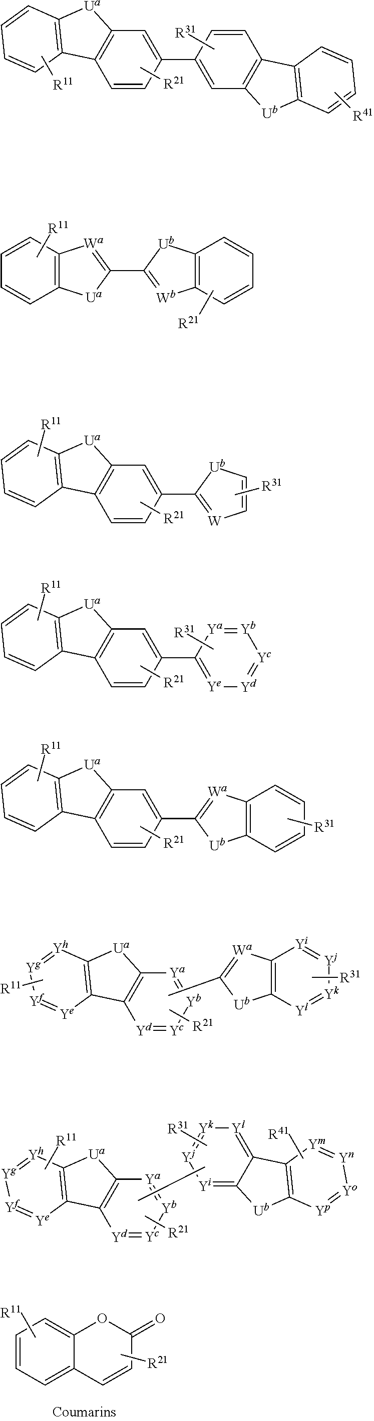

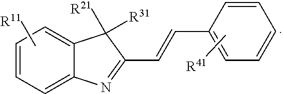

R¹¹, R²¹, R³¹, R⁴¹, R⁵¹, R⁶¹, R⁷¹ and R⁸¹ are selected from hydrogen, deuterium, halogen, hydroxyl, mercaptol, nitro, cyanide, nitrile, isonitrile, sulfonyl, sulfhydryl, sulfonyl, carboxyl, hydrazine; substituted or unsubstituted aryl, cycloalkyl, cyclenyl, heterocyclic, heterocyclic, heterocyclic, hetero-aryl, chain alkyl, alkenyl, acetyl, amino, monoalkylamino, dialkylamino, monoaryl, diaryl, alkoxy, Aryl, haloalkyl, aromatic alkyl, ester group, alkoxy carbonyl, amide group, alkoxamide group, aryl oxamide group, sulfonamide group, amine sulfonyl group, amine formyl group, alkanthio, ureyl, phosphoramide, methylsilyl, polymer, or the substituents formed by the conjugation of the above substituents, or the substituents formed by the combination of the substituents independently, respectively;

Y^{a}, Y^{b}, Y^{c}, Y^{d}, Y^{e}, Y^{f}, Y^{g}, Y^{h}, Yⁱ, Y^{j}, Y^{k}, Y^{l}, Y^{m}, Yⁿ, Y^{o} and Y^{p} are selected from carbon, nitrogen or boron atoms independently, respectively;

U^{a}, U^{b} and U^{c} are selected from CH₂, CRR, CIO, SiRR, GeH₂, GeRR, NH, NR, PH, PR, RP═O, AsR, RAs═O, O, S, Sino, SO₂, se, Se═O, SeO₂, BH, Br, RBi═O, BiH or BiR independently, respectively; R is selected from hydrogen, deuterium, halogen, hydroxyl, mercaptol, nitro, cyanide, nitrile, isonitrile, sulfonyl, sulfhydryl, sulfonyl, carboxyl, hydrazine; substituted or unsubstituted aryl, cycloalkyl, cyclenyl, heterocyclic, heterocyclic, heterocyclic, hetero-aryl, chain alkyl, alkenyl, acetyl, amino, monoalkylamino, dialkylamino, monoaryl, diaryl, alkoxy, aryl, haloalkyl, aromatic alkyl, ester group, alkoxy carbonyl, amide group, alkoxamide group, aryl oxamide group, sulfonamide group, amine sulfonyl group, amine formyl group, alkanthio, ureyl, phosphoramide, methylsilyl, polymer, or the substituents formed by the conjugation of the substituents, or the substituents formed by the combination of the substituents independently, respectively.

As an improvement of the luminescent device in the invention, the metal-assisted delayed fluorescence sensitizer is selected from a compound shown by the following structural formulas:

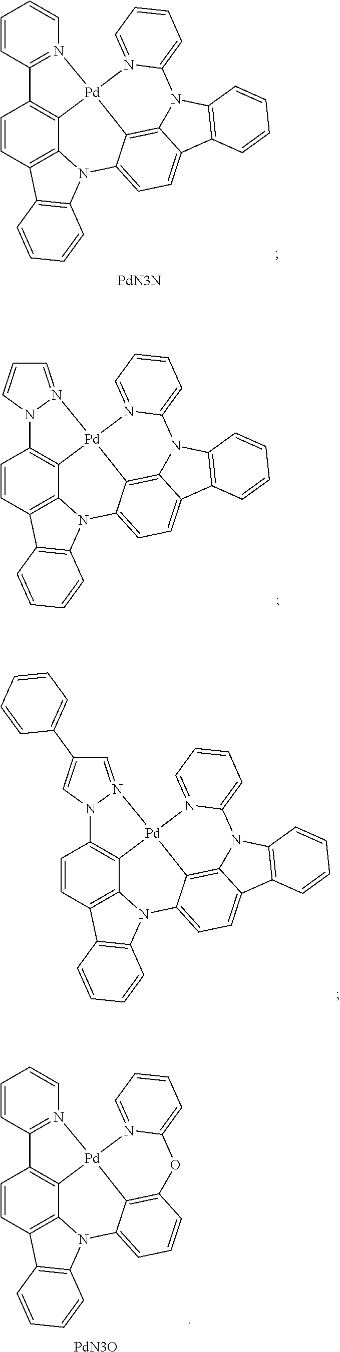

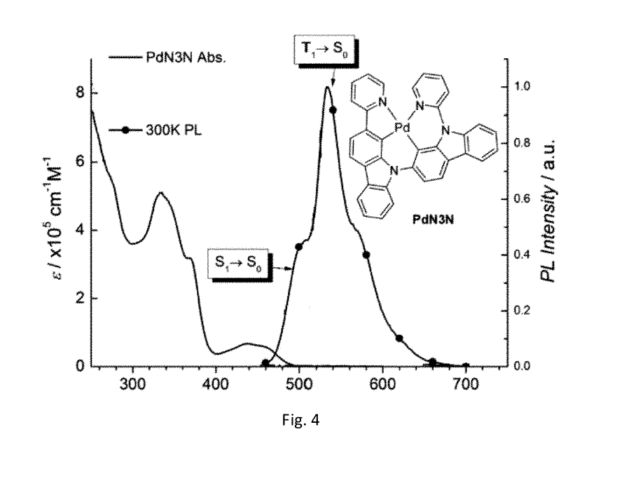

Taking PdN3N for example, the absorption spectra and PL spectra at room temperature (photoluminescence) are shown in FIG. 4. PdN3N has a good absorption spectrum in the wavelength of 500 nm and PL emission spectrum from 460 nm to 680 nm. Among them, PL main peak is a strong emission peak of 540 nm caused by the electron transition of T1-S0, and the shoulder peak near 500 nm is caused by S1-S0 electron transition.

And PdN3O also has similar properties of electron transition: S1→S0 and T1→S0.

The host material in the invention can be selected from the host material commonly used in the prior art. The host materials can be selected as blue light host materials, and organic host materials with T1>2.48 EV can be used, such as TCTA, TAPC, MCP, BCP, CBP etc.

Preferably, T1 of the host material is greater than or equal to the S1 of TADF. If the metal-assisted delayed fluorescence sensitizer is a blue light material, such as 2CZPN, the host material needs to select a material with higher T1 energy, such as PPF. If the metal-assisted delayed fluorescence sensitizer material is only a red-green material, it is suitable to choose the host material with T1 energy higher than S1 energy of the metal-assisted delayed fluorescence sensitizer.

As an improvement of the luminescent device in the invention, the fluorescence quenching agent can be selected from: P type delayed fluorescence material can be selected from the blue luminescent material BDAVBi. TADF thermal delay materials can be selected from blue photothermal delayed fluorescence 2CzPN, blue-green photothermal delay fluorescence material 4CzIPN, green photothermal delay fluorescence materials 4CzPN, 4CzTPNs, orange photothermal delayed fluorescence material 4cZtpn-Me and red photothermal delayed fluorescence material 4CzTPN-Ph.

The luminescent device in the invention is an organic light-emitting diode (OLED). In OLED, a first conductive layer or a second conductive layer may be an anode or a cathode. If the first conductive layer is the cathode, the OLED structure is an inverted OLED structure. If the first conductive layer is the anode, it is a normal OLED structure. As shown in FIG. 1; the luminescent device also comprises a hole transport layer and an electron transport layer, which are arranged between the first electrode and the second electrode; the organic luminescent layer is arranged between the hole transport layer and the electron transport layer.

The following embodiments describe all the benefits and characteristics in the invention for the normal OLED structure.

The anode can be ITO, IGO, IGZO, graphene, LTPS, a-Si or other anode materials. The cathode is a kind of metal or metal alloy with low power function, such as aluminum, magnesium, silver, gold, platinum, or such as Mg:Ag alloy etc.

Between the anode and the hole transport layer, there may also be a flattening layer to form an anode/a flattening layer/a hole transport layer/an organic luminescence layer/an electron transport layer/a cathode. The flattening layer can improve the interface morphology of the organic film between the anode and hole transport layer and reduce the energy level between the different films. The flattening layer can make a polymer, such as a CFx film. CFx film is a kind of film formed by chemical dissociation and chemical polymerization of CHF3 precursor gas in plasma slurry. The flattening layer may also be other conductive material that can be modified with anodes, such as CuPc. The flattening layer can also be a kind of high work function material, such as Au, Ni, Pt, C, Si, Ga etc.

The hole transport layer may be a single hole transport layer, generally containing organic compounds of amines, such as TCTA. In order to further improve the hole transport ability and the hole injection ability of the hole transport layer and the anode or organic luminescent layer, the hole transport layer also includes a hole injection layer and a hole transport layer, or an electron barrier layer. For example, the hole transport layer can be a HIL/HTL structure composed of a-NPB/TCTA. Further speaking, the hole transport layer can also be a P-doped structure to improve the hole transport ability, and P-type doping is characterized by the fact that the HOMO energy level of the host material is close to or higher than that of the LUMO level of the guest material (electron absorbing material), so that the charge transfer between the hosts is more efficient. P-doped hole transport materials may be phthalocyanine molecules. For example, the hole transport rate of ZnPc doped with strong electron absorbent material F4-TCNQ is increased by 5 times.

The OLED structure in the invention also comprises an electron transport layer. For example, the electron transport layer may be Alqan, TPBi. In order to improve the carrier balance in the device structure, the electron transport layer is an electron transport layer/an electron injection layer. Among them, the electron injection layer can be a layer of LIF, which can obviously improve the effect of electron injection and reduce the starting voltage.

Furthermore, the electron transport layer is a N-type doped structure. N-type doped structure is composed of electron transport material: metal material. The ratio of electron transfer material to metal material is 1:1. In order to improve the carrier balance or limit the hole mobility, a HBL hole barrier layer can be arranged between the EML and the electron transport layer. The hole barrier layer is a kind of material with very low HOMO and high triplet energy level. For example, the hole barrier is TPBi.

The OLED structure in the invention further comprises a photoextraction-layer CPL deposited on a cathode. The photoextraction-layer CPL is a kind of material with high refractive index to improve the optical effect of the device. For example, NPB, MgF2.

The organic luminescent layer also contains a host material, a metal-assisted delayed fluorescence sensitizer and a fluorescence quenching agent to form a first conductive layer/a hole transport layer/{an organic luminescent layer}n/an electron transport layer/a second conductive layer structure. Wherein, n is a natural number greater than 1. If n is 1, it is a single luminescent layer structure; if n≥2, it is a multi-luminescent layer structure. For example, the white light OLED (WOLED) structure or series OLED (Tam-OLED). In WOLED structure or Tam-OLED structure, there is at least an organic luminescent layer consists of the host material, the metal-assisted delayed fluorescence sensitizer and the fluorescence quenching agent.

In order to graphically prove the excellent characteristics of the luminescent device provided by the present disclosure, the luminescent devices with the following structure are manufactured: an anode/a hole transport layer/{a host material+a metal-assisted delayed fluorescence sensitizer+a fluorescence quenching agent}/an electron transport layer/a cathode.

The manufacture process of the luminescent device in the embodiment of the invention is as follows:

The ITO substrate is a 30 mm×30 mm bottom emitting glass with four luminescent regions, covering a luminescent area of 2 mm×2 mm, and a transmittance of ITO thin film is 90%@550 nm, and its surface roughness Ra<1 nm, and its thickness is 1300 A, with square resistance of 10 ohms per square meters.

The cleaning method of ITO substrate as follows: first it is placed in a container filled with acetone solution, and the container is placed in ultrasonic cleaning machine for 30 minutes, in order to dissolve and remove most of the organic matter attached to the surface of ITO; and then the cleaned ITO substrate is removed and placed on the hot plate for half an hour at high temperature of 120° C., in order to remove most of the organic solvent and water vapor from the surface of the ITO substrate; and then the baked ITO substrate is transferred to the UV-ZONE equipment for processing with O³ Plasma, and the organic matter or foreign body which could not be removed on the ITO surface is further processed by plasma, and the processing time is 15 minutes, and the finished ITO is quickly transferred to the film forming chamber of the OLED evaporation equipment.

OLED preparation before evaporation: first of all, the OLED evaporation equipment is prepared, and then IPA is used to wipe the inner wall of the chamber, in order to ensure that the whole film chamber is free of foreign bodies or dust. Then, the crucible containing OLED organic material and the crucible containing aluminum particles are placed on the position of organic evaporation source and inorganic evaporation source in turn. By closing the cavity and taking the initial vacuum and high vacuum, the internal evaporation degree of OLED evaporation equipment can reach 10⁻⁷ Torr.

OLED evaporation film: the OLED organic evaporation source is opened to preheat the OLED organic material at 100° C. for 15 minutes to ensure the further removal of water vapor from the OLED organic material. Then the organic material that needs to be evaporated is heated rapidly and the baffle over the evaporation source is opened until the evaporation source of the material runs out and the wafer detector detects the evaporation rate, and then the temperature rises slowly, the temperature rise is 1˜5° C., until the evaporation rate is stable at 1 A/s, the baffle directly below the mask plate is opened and the OLED film is formed. When it is observed that the organic film on the ITO substrate reaches the preset film thickness at the computer end, the mask baffle and the evaporative source directly above the baffle are closed, and the evaporative source heater of the organic material is closed. The evaporation process for other organic and cathode metal materials is described above.

OLED encapsulation process: the cleaning and processing of 20 mm×20 mm encapsulation cover is as the same as the pretreatment of ITO substrate. The UV adhesive coating or dispensing is carried out around the epitaxial of the cleaned encapsulation cover, and then the encapsulation cover of the finished UV adhesive is transferred to the vacuum bonding device, and stuck with the ITO substrate of the OLED film in vacuum, and then transferred to the UV curing cavity for UV-light curing at wavelength of 365 nm. The light-cured ITO devices also need to undergo post-heat treatment at 80° C. for half an hour, so that the UV adhesive material can be cured completely. The structure of the luminescent device 10 formed by the above preparation process is as follows:

ITO/TAPC/{a host material+a metal-assisted delayed fluorescence sensitizer+a fluorescence quenching agent}/PPF/TPBi/Mg: Ag.

Among them, TAPC is 90 nm, the organic luminescence layer is 40 nm, PPF is 10 nm, TPBi is 30 nm, Mg: Ag electrode is 100 nm.

The materials used in the embodiment of the invention have following structures:

The metal-assisted delayed fluorescence sensitizer is selected from:

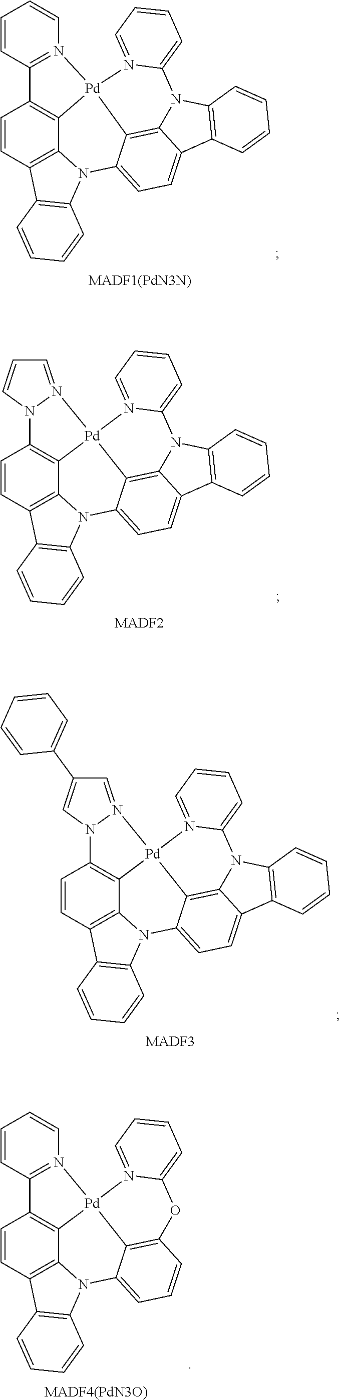

The fluorescence quenching agent is selected from:

A1: blue luminescent material BDAVBi;

A2: blue heat delayed fluorescence 2CzPN;

A3: blue-green photothermal delayed fluorescence material 4CzIPN.

Host material:

H1: TCTA (4,4′,4″-Tris(carbazol-9-yl)triphenylamine);

H2:26DCzPPy (2,6-Bis(3-(9H-Carbazol-9-yl)phenyl)pyridine);

H3: Mcp (1,3-Bis(carbazol-9-yl)benzene).

No. 1˜11 OLED devices are prepared by using the above method and material, in which the material and mass ratio in the organic luminescent layer is shown in Table 1.

Among them, no metal-assisted delayed fluorescence sensitizer is added to the OLED device numbered D1; the OLED device numbered D2 uses a conventional fluorescent material absorbent and the chemical structure is as follows:

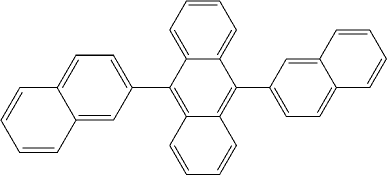 [SMILES: c1ccc2cc(-c3c4ccccc4c(-c4ccc5ccccc5c4)c4ccccc34)ccc2c1]

The IVL maximum external quantum efficiency (EQE) of the encapsulated OLED device is tested, and the McScience IVL device (model M6000) is used. The specific experimental results are shown in Table 1:

TABLE 1

| | | Metal-assisted | | | |
|---|---|---|---|---|---|
| | | delayed | Fluorescence | | |
| | Host | fluorescence | quenching | Mass | |
| No. | material | sensitizer | agent | ratio | EQEₘₐₓ |
| 1 | H1 | MADF1 | A1 | 7:2:1 | 5.7% |
| 2 | H1 | MADF2 | A1 | 7:2:1 | 4.9% |
| 3 | H1 | MADF3 | A1 | 7:2:1 | 4.8% |
| 4 | H1 | MADF1 | A2 | 7:2:1 | 12.6% |
| 5 | H1 | MADF4 | A3 | 7:2:1 | 12.8% |
| 6 | H2 | MADF1 | A2 | 7:2:1 | 12.5% |
| 7 | H3 | MADF1 | A2 | 7:2:1 | 12.4% |
| 8 | H1 | MADF1 | A2 | 4:4:2 | 3.1% |
| 9 | H1 | MADF1 | A2 | 5:3:2 | 3.6% |
| 10 | H1 | MADF1 | A2 | 6:2:2 | 7.3% |
| D1 | H1 | — | A1 | 5:5 [symbol] | 1.8% |
| D2 | H1 | MADF1 | AND | 7:2:1 | 2.3% |

Note:
the mass ratio of 5:5 to fluorescence quenching agent is 5:5 in D1.

In the OLED device numbered D1, the fluorescence luminescence efficiency is the lowest when MADF is not added as sensitizer and only host and guest doped system is included.

In the OLED device numbered D2, MADF is used as the sensitizer, but when the ordinary fluorescent material absorbent is used, the ordinary fluorescent material absorber does not have the function of energy up-conversion. It is not possible to convert all T1 to S1 for fluorescence luminescence, so the fluorescence efficiency is not very high.

In the OLED devices numbered 1˜11, when MADF is used as sensitizer and fluorescence quenching agent with energy up-conversion is used, the fluorescence efficiency can break through 5% theoretical upper limit of traditional fluorescence efficiency.

The P-type delayed fluorescence material (BDAVBi), which is used in the OLED device numbered 1˜3, has been used for up-conversion with TTA. The E-type delayed fluorescence material using TADF thermal delay fluorescence is used in the code 4˜7. According to the data, the luminescence effect of TADF as fluorescence quenching agent is better than that of TTA. This is because the TADF material can obtain 100% fluorescence luminescence in theory, but the highest fluorescence efficiency of 67.5% can be obtained by using TTA as fluorescence quenching agent. But its performance is obviously superior to that of OLED devices with common fluorescent absorbent.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A luminescent device, comprising a first electrode, a second electrode and at least an organic luminescent layer arranged between the first electrode and the second electrode, wherein
the organic luminescent layer comprises a host material, a metal-assisted delayed fluorescence sensitizer and a fluorescence quenching agent;
the metal-assisted delayed fluorescence sensitizer is an organic material which transfers a triplet exciton and a singlet exciton produced by electroluminescence to the fluorescence quenching agent; and
the fluorescence quenching agent is a fluorescent luminescent material which transfers the energy of all the triplet exciton to the singlet exciton and uses the singlet exciton for luminescence.

2. The luminescent device as described in claim 1, wherein the triplet exciton includes the triplet exciton produced by the fluorescence quenching agent itself.

3. The luminescent device as described in claim 1, wherein the host material is an organic material forming a triplet exciton and a singlet exciton; or the host material and the metal-assisted delayed fluorescence sensitizer are organic materials forming the triplet exciton and singlet exciton.

4. The luminescent device as described in claim 1, wherein the material of fluorescence quenching agent is selected from a P type delayed fluorescence material or an E type delayed fluorescence material.

5. The luminescent device as described in claim 1, wherein the mass percentage content of the host material in the organic luminescent layer is A, and the mass percentage content of the metal-assisted delayed fluorescence sensitizer in the organic luminescent layer is B, and the mass percentage content of the fluorescence quenching agent in the organic luminescent layer is C, and the condition A/(A+B+C)>60% should be satisfied.

6. The luminescent device as described in claim 1, wherein the mass percentage content of the host material in the organic luminescent layer is A, and the mass percentage content of the metal-assisted delayed fluorescence sensitizer in the organic luminescent layer is B, and the mass percentage content of the fluorescence quenching agent in the organic luminescent layer is C, and the condition B/(A+B+C)<30% should be satisfied.

7. The luminescent device as described in claim 1, wherein the mass percentage content of the host material in the organic luminescent layer is A, and the mass percentage content of the metal-assisted delayed fluorescence sensitizer in the organic luminescent layer is B, and the mass percentage content of the fluorescence quenching agent in the organic luminescent layer is C, and the condition C/(A+B+C)<20% should be satisfied.

8. The luminescent device as described in claim 1, wherein the Δ E_{(S1-T1)} of the metal-assisted delayed fluorescence material is less than 0.3 Ev, and the metal-assisted delayed fluorescence material can simultaneously utilize the triplet exciton and singlet exciton for luminescence at room temperature or high temperature.

9. The luminescent device as described in claim 1 further comprising a hole transport layer and an electronic transmission layer; wherein the hole transport layer and the electron transport layer are arranged between the first electrode and the second electrode; and the organic luminescent layer is arranged between the hole transport layer and the electron transport layer.

10. The luminescent device as described in claim 1, wherein the metal-assisted delayed fluorescence sensitizer is selected from a compound shown in the following general formula: 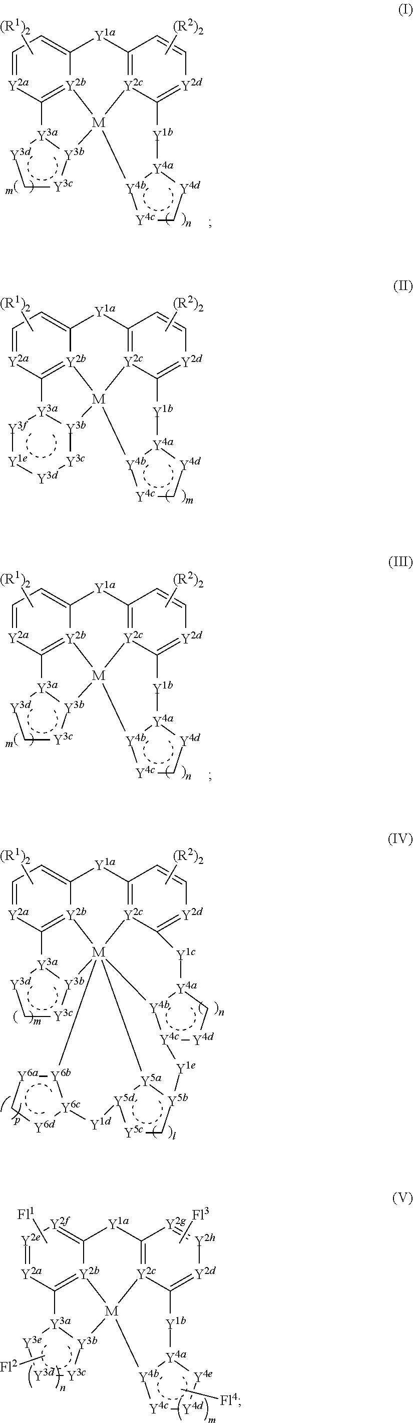
where,
M denotes Pt, Pd, Ni, Mg, Zn, Au, Ag, Cu, Ir, Ru, Co;
in the general formula I:
M denotes Ir, Rh, Ni, Cu, Ag;
R¹ or R² denotes hydrogen atoms, halogen atoms, hydroxyl groups, mercaptan groups, amino groups, substituted or unsubstituted alkyl, substituted or unsubstituted alkynes, substituted or unsubstituted naphthenic, substituted or unsubstituted cycloolefin, substituted or unsubstituted alkoxyl independently, respectively;
Y^{1a} or Y^{1b} denotes O, NR³, CR³R⁴, S, AsR³, BR³, PR³, P(O)R³, SiR³R⁴ independently, respectively, R³ or R⁴ is selected from hydrogen atoms, halogen atoms, hydroxyl groups, mercaptyl groups, amino groups, substituted or unsubstituted alkyl groups, substituted or unsubstituted alkynes, substituted or unsubstituted naphthenic alkyl, substituted or unsubstituted cycloalkenes, substituted or unsubstituted alkoxyl;
Y^{2a}, Y^{2b}, Y^{2c} or Y^{2d} denotes N and CR⁵ independently, respectively, and R⁵ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloalkenes, substituted or unsubstituted alkoxyl;
Y^{3a}, Y^{3b}, Y^{3c}, Y^{3d}, Y^{4a}, Y^{4b}, Y^{4c}, Y^{4d} denote N, O, S, NR⁶, CR⁷ independently, respectively; R⁶ or R⁷ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloolefins, substituted or unsubstituted alkoxyl;
m is 1 or 2, n is 1 or 2; [symbol]
represents an unsaturated ring;
in the general formula II:
M denotes Pt, Pd, Au;
R¹ or R² denotes hydrogen atoms, halogen atoms, hydroxyl groups, mercaptan groups, amino groups, substituted or unsubstituted alkyl, substituted or unsubstituted alkynes, substituted or unsubstituted naphthenic, substituted or unsubstituted cycloolefin, substituted or unsubstituted alkoxyl independently, respectively;
Y^{1a} or Y^{1b} denotes O, NR³, CR³R⁴, S, AsR³, BR³, PR³, P(O)R³, SiR³R⁴ independently, respectively, and R³ or R⁴ is selected from hydrogen atoms, halogen atoms, hydroxyl groups, mercaptyl groups, amino groups, substituted or unsubstituted alkyl groups, substituted or unsubstituted alkynes, substituted or unsubstituted naphthenic alkyl, substituted or unsubstituted cycloalkenes, substituted or unsubstituted alkoxyl;
Y^{2a}, Y^{2b}, Y^{2c}, Y^{2d} denotes N and CR⁵ independently, respectively, and R⁵ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloalkenes, substituted or unsubstituted alkoxyl;
Y^{3a}, Y^{3b}, Y^{3c}, Y^{3d}, Y^{4a}, Y^{4b}, Y^{4c}, Y^{4d} denotes N, O, S, NR⁶, CR⁷ independently, respectively; R⁶ or R⁷ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloolefins, substituted or unsubstituted alkoxyl;
M is 1 or 2; [symbol]
represents an unsaturated ring;
in the general formula III:
M is Pt, Pd, Au, Ag;
R¹ or R² denotes hydrogen atoms, halogen atoms, hydroxyl groups, mercaptan groups, amino groups, substituted or unsubstituted alkyl, substituted or unsubstituted alkynes, substituted or unsubstituted naphthenic, substituted or unsubstituted cycloolefin, substituted or unsubstituted alkoxyl independently, respectively;
One of Y^{1a} or Y^{1b} denotes B(R3)₂, and the other denotes O, NR³, CR³R⁴, S, AsR³, BR³, PR³, P(O)R³, SiR³R⁴, and R³ or R⁴ is selected from hydrogen atoms, halogen atoms, hydroxyl groups, mercaptyl groups, amino groups, substituted or unsubstituted alkyl groups, substituted or unsubstituted alkynes, substituted or unsubstituted naphthenic alkyl, substituted or unsubstituted cycloalkenes, substituted or unsubstituted alkoxyl;
Y^{2a}, Y^{2b}, Y^{2c}, Y^{2d} denotes N and CR⁵ independently, respectively, and R⁵ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloalkenes, substituted or unsubstituted alkoxyl;
Y^{3a}, Y^{3b}, Y^{3c}, Y^{3d}, Y^{4a}, Y^{4b}, Y^{4c}, Y^{4d} denotes N, O, S, NR⁶, CR⁷ independently, respectively; R⁶ or R⁷ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloolefins, substituted or unsubstituted alkoxyl;
m is 1 or 2, n is 1 or 2; [symbol]
represents an unsaturated ring;
in the general formula IV:
M denotes Ir, Rh, Os, Co, Ru;
R¹ or R² denotes hydrogen atoms, halogen atoms, hydroxyl groups, mercaptan groups, amino groups, substituted or unsubstituted alkyl, substituted or unsubstituted alkynes, substituted or unsubstituted naphthenic, substituted or unsubstituted cycloolefin, substituted or unsubstituted alkoxyl independently, respectively;
Y^{1a}, Y^{1b}, Y^{1c}, Y^{1d} denotes O, NR³, CR³R⁴, S, AsR³, BR³, PR³, P(O)R³ and SiR³R⁴ independently, respectively, and R³ or R⁴ is selected from hydrogen atoms, halogen atoms, hydroxyl groups, mercaptyl groups, amino groups, substituted or unsubstituted alkyl groups, substituted or unsubstituted alkynes, substituted or unsubstituted naphthenic alkyl, substituted or unsubstituted cycloalkenes, substituted or unsubstituted alkoxyl;
Y^{1e} denotes virtual atoms, O, NR³, CR³R⁴, S, AsR³, BR³, PR³, P(O)R³, SiR³R⁴, and R³ or R⁴ is selected from hydrogen atoms, halogen atoms, hydroxyl groups, mercaptyl groups, amino groups, substituted or unsubstituted alkyl groups, substituted or unsubstituted alkynes, substituted or unsubstituted naphthenic alkyl, substituted or unsubstituted cycloalkenes, substituted or unsubstituted alkoxyl; the virtual atom indicates that the group does not exist;
Y^{2a}, Y^{2b}, Y^{2c}, Y^{2d} denotes N and CR⁵ independently, respectively, and R⁵ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloalkenes, substituted or unsubstituted alkoxyl;
Y^{3a}, Y^{3b}, Y^{3c}, Y^{3d}, Y^{4a}, Y^{4b}, Y^{4c}, Y^{4d} denotes N, O, S, NR⁶, CR⁷ independently, respectively; R⁶ or R⁷ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloolefins, substituted or unsubstituted alkoxyl;
m=1 or 2, n=1 or 2, l=1 or 2; [symbol]
represents an unsaturated ring;
in the general formula V:
M is Pt, Pd, Au, Ir, Rh, Ni, Cu, Ag;
Y^{1a} or Y^{1b} denotes O, NR³, CR³R⁴, S, CR³R⁴, S, AsR³, BR³, PR³, P(O)R³, SiR³R⁴ independently, respectively, and R³ or R⁴ is selected from hydrogen atoms, halogen atoms, hydroxyl groups, mercaptyl groups, amino groups, substituted or unsubstituted alkyl groups, substituted or unsubstituted alkynes, substituted or unsubstituted naphthenic alkyl, substituted or unsubstituted cycloalkenes, substituted or unsubstituted alkoxyl;
Y^{2a}, Y^{2b}, Y^{2c} Y^{2d} denotes N, CR⁵ independently, respectively, and R⁵ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloalkenes, substituted or unsubstituted alkoxyl;
Y^{3a}, Y^{3b}, Y^{3c}, Y^{3d}, Y^{4a}, Y^{4b}, Y^{4c}, Y^{4d} denotes N, O, S, NR⁶, CR⁷ independently, respectively; R⁶ or R⁷ is selected from hydrogen atoms, halogen atoms, hydroxyl groups, mercaptyl groups, amino groups, substituted or unsubstituted alkyl groups, substituted or unsubstituted alkynes, substituted or unsubstituted cycloalkyl, substituted or unsubstituted cycloolefins, substituted or unsubstituted alkoxyl;
m is 1 or 2, n is 1 or 2; [symbol]
represents an unsaturated ring;
FI¹, FI², FI³, FI⁴ denotes fluorescent illuminant independently, respectively, and FI¹, FI², FI³, FI⁴ exit independently and at least one of them exists;
If FI¹, FI², FI³, FI⁴ exist, at least one of the FI¹, the FI², the FI³ and the FI⁴ is associated with Y^{2a}, Y^{2d}, Y^{2e}, Y^{2f}, Y^{2g}, Y^{2h}, Y^{3c}, Y^{3d}, Y^{3e}, Y^{4c}, Y^{4d}, Y^{4e} by covalent bonds.

11. The luminescent device as described in claim 10, wherein the FI¹, FI², FI³, FI⁴ denotes substituted or unsubstituted C1˜24 alkyl, substituted or unsubstituted C2˜24 alkyl, substituted or unsubstituted C2˜24 alkyl, substituted or unsubstituted C6-72 aryl, substituted or unsubstituted C6-72 hetero aryl independently, respectively; the substituents are selected from halogen, nitro, hydroxyl, cyanide, nitrile, isonitrile, amino, sulfhydryl, mercaptol, sulfonyl, sulfonyl, carboxyl, hydrazine, C6˜24 aryl, C6˜24 aryl group, C6˜24 aryl group, C1˜12alkyl group, C2˜12 enyl group.

12. The luminescent device as described in claim 1, wherein the metal-assisted delayed fluorescence sensitizer is selected from compounds shown by the following structural formulas: [chemical structure]
